(19) United States
(12) Patent Application Publication
(10) Pub. No.: US 2025/0174278 A1
(43) Pub. Date: May 29, 2025

(54) METHOD OF OPERATING MEMORY DEVICE

(71) Applicant: SK hynix Inc., Icheon-si Gyeonggi-do (KR)

(72) Inventors: June Young CHOI, Icheon-si Gyeonggi-do (KR); Sang Ha LEE, Icheon-si Gyeonggi-do (KR)

(73) Assignee: SK hynix Inc., Icheon-si Gyeonggi-do (KR)

(21) Appl. No.: 18/677,302

(22) Filed: May 29, 2024

(30) Foreign Application Priority Data
Nov. 27, 2023 (KR) 10-2023-0166541

(51) Int. Cl. G11C 16/10; G11C 16/04; G11C 16/24; H10B 43/10; H10B 43/27; H10B 43/35

(52) U.S. Cl. CPC G11C 16/10; G11C 16/24; G11C 16/0483; H10B 43/10; H10B 43/27; H10B 43/35

(57) ABSTRACT

Provided herein is a method of operating a memory device. The method of operating a memory device may include precharging a first channel of a first plug corresponding to a first select line and a second channel of a second plug corresponding to a second select line, applying one of a program-enable voltage and a program-inhibit voltage to the first channel, applying one of the program-enable voltage and the program-inhibit voltage to the second channel, and programming memory cells selected from among memory cells included in the first plug and the second plug.

### CROSS-REFERENCE TO RELATED APPLICATION

The present application claims priority under 35 U.S.C. § 119(a) to Korean patent application number 10-2023-0166541, filed on Nov. 27, 2023, in the Korean Intellectual Property Office, the entire disclosure of which application is incorporated herein by reference.

### BACKGROUND

### 1. Technical Field

Various embodiments of the present disclosure generally relate to a method of operating a memory device, and more particularly to a method of operating a memory device having a three-dimensional (3D) structure.

### 2. Related Art

A memory device may include a memory cell array in which data is stored, and a peripheral circuit which is configured to perform a program operation, a read operation, or an erase operation on the memory cell array.

The memory cell array may include a plurality of memory blocks disposed between bit lines and a source line, and each of the memory blocks may include plugs extending from a substrate, for example, in a vertical direction. Each of the plugs may include source select transistors, memory cells, and drain select transistors.

Gates of the source select transistors may be coupled to a source select line, gates of the memory cells may be coupled to word lines, and gates of the drain select transistors may be coupled to drain select lines.

Among the drain select lines coupled to a selected memory block, one drain select line may be selected, and the remaining drain select lines may be unselected.

Because memory cells corresponding to the selected drain select line and memory cells corresponding to the unselected drain select lines are coupled to the same word lines, threshold voltages of the unselected memory cells included in plugs of the unselected drain select lines may increase while the selected memory cells included in plugs of the selected drain select line are programmed.

### SUMMARY

An embodiment of the present disclosure may provide for a method of operating a memory device. The method may include precharging a first channel of a first plug corresponding to a first select line and a second channel of a second plug corresponding to a second select line, applying one of a program-enable voltage and a program-inhibit voltage to the first channel, applying one of the program-enable voltage and the program-inhibit voltage to the second channel, and programming memory cells selected from among memory cells included in the first plug and the second plug.

An embodiment of the present disclosure may provide for a method of operating a memory device. The method may include precharging a first channel of a first plug and a second channel of a second plug, wherein the first plug and the second plug correspond to a first select line, precharging a third channel of a third plug and a fourth channel of a fourth plug, wherein the third channel and the fourth channel correspond to a second select line, applying one of a program-enable voltage and a program-inhibit voltage to each of the first channel, the second channel, the third channel, and the fourth channel, and programming memory cells selected from among memory cells included in the first plug, the second plug, the third plug, and the fourth plug.

An embodiment of the present disclosure may provide for a method of operating a memory device. The method may include precharging a first channel of a first plug corresponding to a first select line, a second channel of a second plug corresponding to the first line, a third channel of a third plug corresponding to a second select line, and a fourth channel of a fourth plug corresponding to a second select line; when the first plug and the third plug are selected plugs, applying a program-enable voltage to the first channel of the first plug and the third channel of the third plug; when the second plug and the fourth plug are unselected plugs, applying a program-inhibit voltage to the second channel of the second plug and the fourth channel of the fourth plug; and programming selected memory cells from among memory cells included in the first plug and the third plug of a memory block.

### BRIEF DESCRIPTION OF THE DRAWINGS

FIG. 1 is a diagram illustrating a memory device according to an embodiment of the present disclosure.

FIG. 2 is a diagram illustrating an arrangement of a memory cell array and a peripheral circuit according to an embodiment of the present disclosure.

FIG. 3 is a circuit diagram illustrating a memory block according to an embodiment of the present disclosure.

FIG. 4 is a flowchart illustrating a program operation method for a memory device according to the present disclosure.

FIG. 5 is a perspective view illustrating the structure of a memory block according to a first embodiment of the present disclosure.

FIG. 6 is a layout view illustrating a connection relationship between a memory block and page buffers according to a first embodiment of the present disclosure.

FIG. 7A and FIG. 7B are tables including voltages and transistor states during a program operation according to a first embodiment of the present disclosure when at least one of plugs is unselected.

FIG. 8A and FIG. 8B are tables including voltages and transistor states during a program operation according to a first embodiment of the present disclosure when all plugs are selected plugs.

FIG. 9A and FIG. 9B are diagrams for sequentially explaining a program operation according to a first embodiment of the present disclosure when all plugs are unselected plugs.

FIG. 10 is a perspective view illustrating the structure of a memory block according to a second embodiment of the present disclosure.

FIG. 11 is a layout view illustrating a connection relationship between a memory block and page buffers according to a second embodiment of the present disclosure.

FIG. 12A and FIG. 12B are tables including voltages and transistor states during a program operation according to a second embodiment of the present disclosure when at least one of plugs is unselected.

FIG. 13A and FIG. 13B are tables including voltages and transistor states during a program operation according to a second embodiment of the present disclosure when all plugs are selected plugs.

FIG. 14A and FIG. 14B are tables including voltages and transistor states during a program operation according to a second embodiment of the present disclosure when all plugs are unselected plugs.

FIG. 15 is a perspective view illustrating the structure of a memory block according to a third embodiment of the present disclosure.

FIG. 16 is a layout view illustrating a connection relationship between a memory block and page buffers according to a third embodiment of the present disclosure.

FIG. 17A and FIG. 17B are tables including voltages and transistor states during a program operation according to a third embodiment of the present disclosure when at least one of plugs is unselected.

FIG. 18A and FIG. 18B are tables including voltages and transistor states during a program operation according to a third embodiment of the present disclosure when all plugs are selected plugs.

FIG. 19A and FIG. 19B are tables including voltages and transistor states during a program operation according to a third embodiment of the present disclosure when all plugs are unselected plugs.

FIG. 20 is a diagram illustrating an embodiment of a memory card system including a memory device according to the present disclosure.

FIG. 21 is a diagram illustrating an embodiment of a solid state drive (SSD) system including a memory device according to the present disclosure.

### DETAILED DESCRIPTION

Specific structural or functional descriptions, disclosed herein, describe embodiments according to the concepts of the present disclosure. The embodiments according to the concepts of the present disclosure should not be construed as limited to embodiments described below and may be modified in various forms and replaced with other equivalent embodiments.

Although the terms “first” and “second” may be used herein to describe various elements, these elements should not be limited by these terms. The terms are used to distinguish one element from other elements. The phrase “arranged on” includes disposed on or above or touching, but not necessarily making electrical contact. Contact, as used herein, includes an electrical coupling or an electrical connection. Terms such as “top,” “bottom,” “above,” “below,” “under,” “over,” “upper,” “lower,” “uppermost,” “vertical,” and other terms implying spatial relationship are utilized only for the purpose of ease of description or reference to a drawing and are not otherwise limiting.

Various embodiments of the present disclosure are described in detail with reference to the accompanying drawings. The cross-hatching throughout the figures illustrates corresponding or similar areas between the figures rather than indicating the materials for the areas.

Various embodiments of the present disclosure are directed to a method of operating a memory device, which method can suppress an increase in the threshold voltages of unselected memory cells.

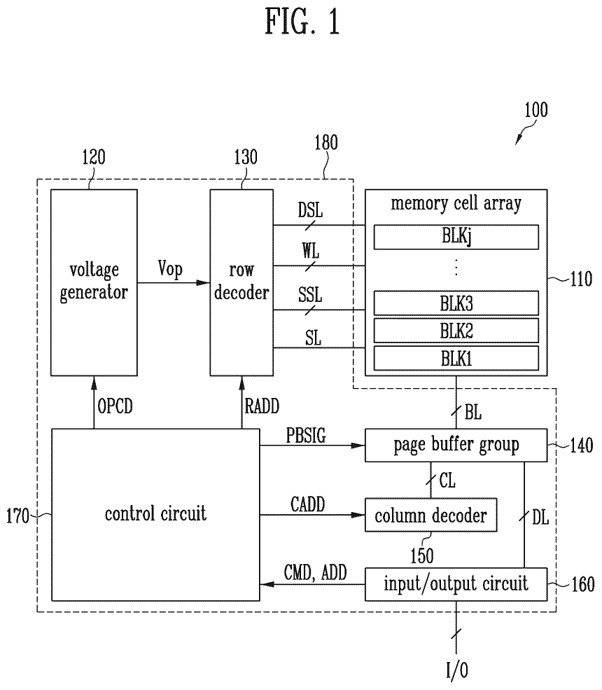

FIG. 1 is a diagram illustrating a memory device.

Referring to FIG. 1, a memory device 100 includes a memory cell array 110 and a peripheral circuit 180.

The memory cell array 110 includes a first memory block BLK1 to a j-th memory block BLKj, where j is a positive integer. When the memory blocks BLK1 to BLKj are referenced, each of memory block BLK1, memory block BLK2, memory block BLK3, . . . , through memory block BLKn, such as memory block BLK1 through BLKj, are included. Each of the memory blocks BLK1 to BLKj includes memory cells capable of storing data. Drain select lines DSL, word lines WL, source select lines SSL, and a source line SL are coupled to each of the memory blocks BLK1 to BLKj, and bit lines BL are coupled in common to the memory blocks BLK1 to BLKj.

Each of the memory blocks BLK1 to BLKj is formed as a three-dimensional (3D) structure. Each memory block having a 3D structure includes memory cells stacked on a substrate in, for example, a vertical or Z direction as shown in the drawings.

According to a program scheme, each memory cell stores 1 bit of data or 2 or more bits of data. For example, a scheme that stores 1 bit of data in one memory cell is referred to as a single-level cell (SLC) scheme, and a scheme that stores 2 bits of data in one memory cell is referred to as a multi-level cell (MLC) scheme. A scheme that stores 3 bits of data in one memory cell is referred to as a triple-level cell (TLC) scheme, and a scheme that stores 4 bits of data in one memory cell is referred to as a quad-level cell (QLC) scheme.

The peripheral circuit 180 performs a program operation including storing data in the memory cell array 110, a read operation including outputting data stored in the memory cell array 110, and an erase operation including erasing data stored in the memory cell array 110. For example, the peripheral circuit 180 includes a voltage generator 120, a row decoder 130, a page buffer group 140, a column decoder 150, an input/output circuit 160, and a control circuit 170.

The voltage generator 120 generates various operating voltages Vop that are used for any of a program operation, a read operation, and an erase operation in response to an operation code OPCD. For example, the voltage generator 120 generates program voltages, turn-on voltages, turn-off voltages, negative voltages, precharge voltages, verify voltages, read voltages, pass voltages, and erase voltages in response to the operation code OPCD. The operating voltages Vop generated by the voltage generator 120 are applied to the drain select lines DSL, the word lines WL, the source select lines SSL, and the source line SL of a memory block selected by the row decoder 130.

The program voltages are voltages that are applied to the selected word line among the word lines WL during a program operation and are used to increase the threshold voltages of memory cells coupled to the selected word line. The turn-on voltages are applied to the drain select lines DSL and the source select lines SSL, and are used to turn on drain select transistors and source select transistors. The turn-off voltages are applied to the drain select lines DSL and the source select lines SSL and are used to turn off the drain select transistors and the source select transistors. For example, the turn-off voltages may be 0 V. The precharge voltages may be voltages higher than 0 V and are applied to the bit lines during a read operation. The verify voltages are used during a verify operation including determining whether the threshold voltages of selected memory cells are increased to a target level. The verify voltages may be set to various levels according to the target level and are applied to the selected word line.

The read voltages are applied to the selected word line during a read operation performed on the selected memory cells. For example, the read voltages may be set to various levels according to the program scheme for the selected memory cells. The pass voltages are voltages that are applied to unselected word lines among the word lines WL during a program or read operation and are used to turn on memory cells coupled to the unselected word lines.

The erase voltages are used during an erase operation including erasing the memory cells included in the selected memory block and are applied to the source line SL.

The row decoder 130 is configured to transmit the operating voltages Vop to the drain select lines DSL, the word lines WL, the source select lines SSL, and the source line SL, each of which are coupled to a memory block selected according to a row address RADD. For example, the row decoder 130 is coupled to the voltage generator 120 through global lines GL and is coupled to the memory blocks BLK1 to BLKj through the drain select lines DSL, the word lines WL, the source select lines SSL, and the source line SL.

The page buffer group 140 includes a plurality (j) of page buffers (not illustrated) coupled to the memory blocks BLK1 to BLKj, respectively. The page buffers are coupled to the memory blocks BLK1 to BLKj through corresponding bit lines BL. During a read operation, the page buffers, in response to page buffer control signals PBSIG, sense the currents or voltages of the bit lines, which currents or voltages vary with the threshold voltages of the selected memory cells and temporarily store the sensed data.

The column decoder 150 is configured to facilitate data transfer between the page buffer group 140 and the input/output circuit 160 in response to receiving a column address CADD. For example, the column decoder 150 is coupled to the page buffer group 140 through column lines CL and transmits enable signals through the column lines CL. The page buffers included in the page buffer group 140 receive or output data through data lines DL to the input/output circuit 160 in response to the enable signals.

The input/output circuit 160 is configured to receive or output a command CMD, an address ADD, and data through input/output lines I/O. For example, the input/output circuit 160 transmits the command CMD and the address ADD, received from an external controller through the input/output lines I/O, to the control circuit 170, and transmits the data, received from the external controller through the input/output lines I/O, to the page buffer group 140. Alternatively, the input/output circuit 160 outputs data DATA, received from the page buffer group 140, to the external controller through the input/output lines I/O.

The control circuit 170 may output the operation code OPCD, the row address RADD, the page buffer control signals PBSIG, and the column address CADD in response to the command CMD and the address ADD. For example, when the command CMD input to the control circuit 170 is a command corresponding to a program operation, the control circuit 170 controls the devices included in the peripheral circuit 180 such that the program operation is performed on a memory block selected by the address ADD. When the command CMD input to the control circuit 170 is a command corresponding to a read operation, the control circuit 170 controls the devices included in the peripheral circuit 180 such that the read operation is performed on a memory block selected by the address and read data is output. When the command CMD input to the control circuit 170 is a command corresponding to an erase operation, the control circuit 170 controls the devices included in the peripheral circuit 180 such that the erase operation is performed on a selected memory block.

The control circuit 170 changes and output the operation code OPCD and the page buffer control signals PBSIG such that a plurality of plugs coupled to different drain select lines in a selected memory block are simultaneously programmed during a program operation. For example, the control circuit 170 outputs the operation code OPCD to apply a turn-on voltage to a plurality of drain select lines coupled to the selected memory block and outputs the page buffer control signals PBSIG to select the plurality of plugs coupled to the plurality of drain select lines.

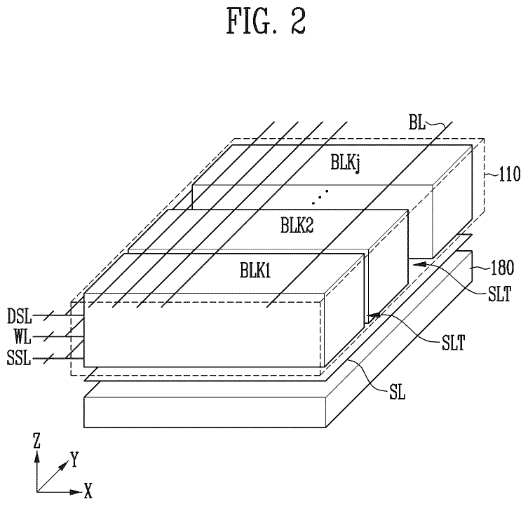

FIG. 2 is a diagram illustrating the arrangement of a memory cell array and a peripheral circuit.

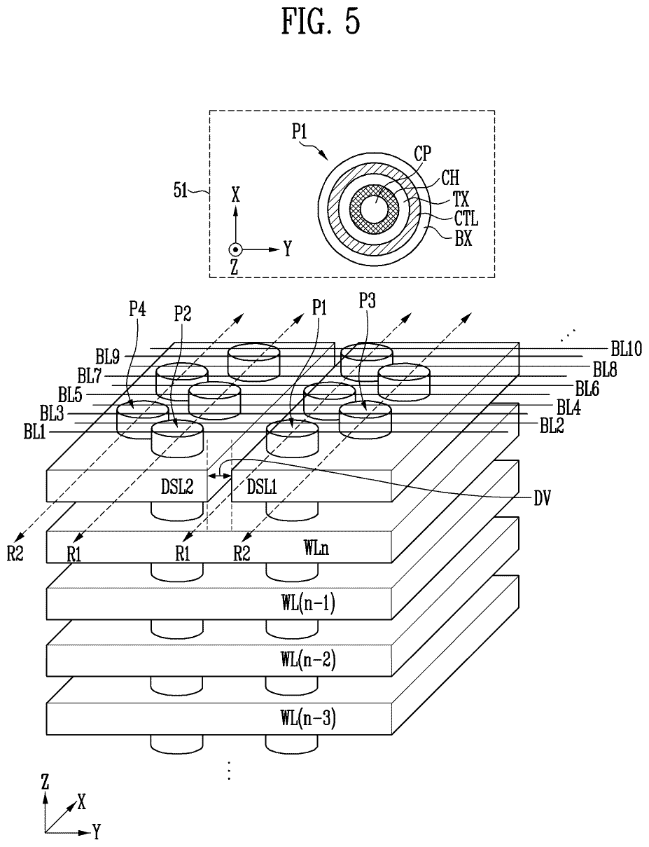

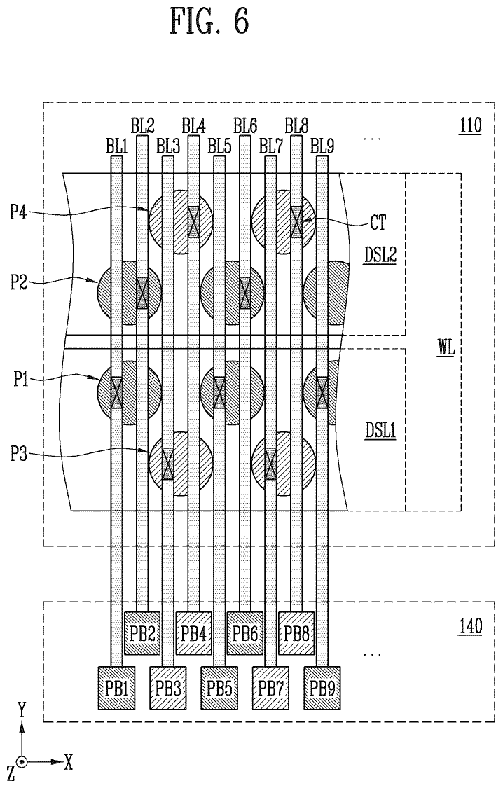

Referring to FIG. 2, the memory cell array 110 is disposed on the peripheral circuit 180. The memory cell array 110 includes memory blocks BLK1 to BLKj. Each of the memory blocks BLK1 to BLKj includes plugs (for example, as shown in FIG. 5 or FIG. 6) extending in a Z direction. Each of the plugs includes source select transistors, memory cells, and drain select transistors. The memory blocks BLK1 to BLKj are spaced apart from each other along a Y direction and extend along an X direction. Consecutive memory blocks BLK1 to BLKj may be separated by a slit SLT.

The memory blocks BLK1 to BLKj may be disposed between bit lines BL and a source line SL. The bit lines BL may be disposed on the memory blocks BLK1 to BLKj, and the source line SL may be disposed under the memory blocks BLK1 to BLKj. Thus, the source line SL may be disposed between the memory cell array 110 and the peripheral circuit 180. The bit lines BL may be coupled to the plugs at the top of the memory blocks BLK1 to BLKj, and the source line SL may be coupled to the plugs at the bottom of the memory blocks BLK1 to BLKj.

Although the bit lines BL are disposed on or above the memory cell array 110 and the source line SL is disposed under the memory cell array 110 as illustrated in FIG. 2, the source line SL may be disposed on or above the memory cell array 110 and the bit lines BL may be disposed under or below the memory cell array 110.

Although embodiments of the present disclosure described herein are based on a structure where the bit lines BL are disposed on or above the memory cell array 110, the embodiments of the present disclosure also apply to a structure where the bit lines BL are disposed under or below the memory cell array 110.

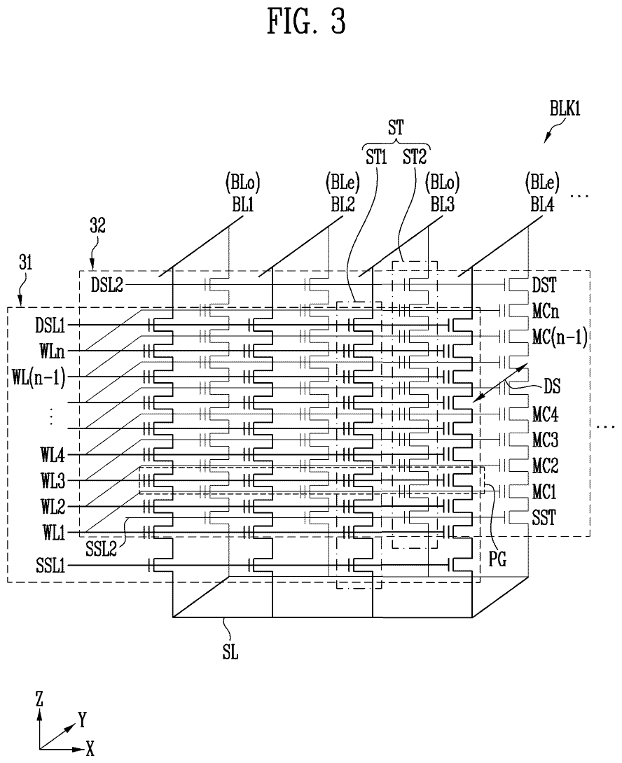

FIG. 3 is a circuit diagram illustrating a memory block.

Referring to FIG. 3, the first memory block BLK1 among the memory blocks BLK1 to BLKj, for example as shown in FIG. 2, is illustrated by way of example.

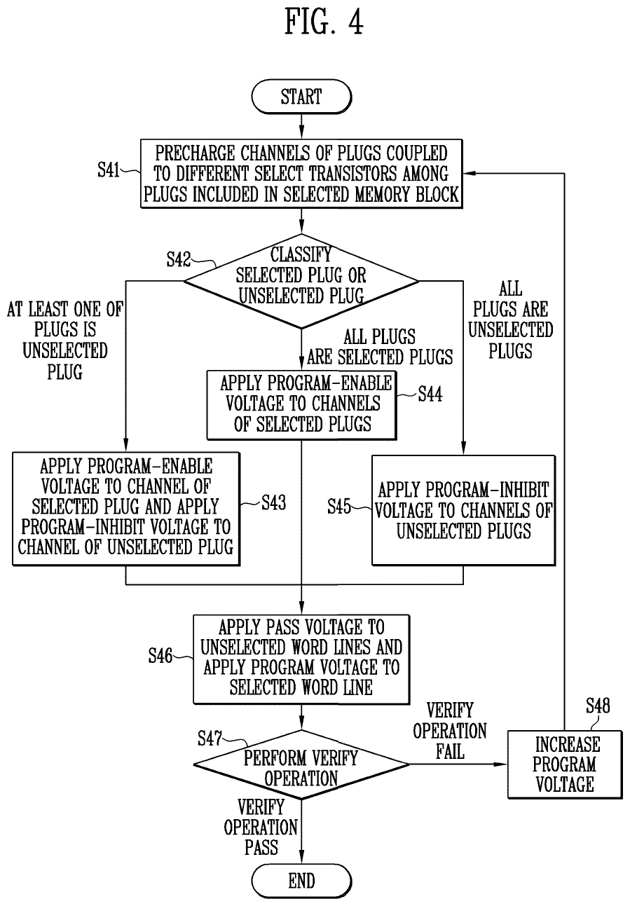

The first memory block BLK1 includes a plurality of cell strings ST coupled between a source line SL and a first bit line BL1 through a fourth bit line BL4. The cell strings ST are included in plugs. The plugs are described with reference to FIG. 4. Although the four bit lines BL1 to BL4 are illustrated in FIG. 3, additional bit lines may be coupled to each of the memory blocks. Depending on the arrangement order, the first bit line BL1 and the third bit line BL3 are odd bit lines BLo, and the second bit lines BL2 and fourth bit line BL4 are even bit lines BLe.

The cell strings ST are coupled in common to the source line SL. Among the cell strings ST, cell strings ST arranged along an X direction are coupled to the first bit line BL1 to the fourth bit line BL4 and cell strings ST arranged along a Y direction are coupled to any one of the bit lines BL1 to BL4.

Each of the cell strings ST includes a source select transistor SST, memory cells MC1 to MCn, and a drain select transistor DST.

The source select transistor SST is coupled between the source line SL and the first memory cell MC1, and the drain select transistor DST is coupled between the n-th memory cell MCn and the corresponding bit line, where n is a positive integer. The memory cells MC1 to MCn are coupled between the source select transistor SST and the drain select transistor DST. The quantity of drain select transistors DST and the quantity of source select transistors SST are not limited to those illustrated in FIG. 3. In addition to the memory cells MC1 to MCn, dummy cells may be coupled between the drain select transistor DST and the source select transistor SST. The memory cells MC1 to MCn store user data or normal data, and the dummy cells store dummy data.

Gates of drain select transistors DST included in different cell strings ST are coupled to the drain select line DSL1 or DSL2. Gates of the memory cells MC1 to MCn included in different cell strings ST are coupled to word lines WL1 to WLn, respectively. Gates of source select transistors SST included in different cell strings ST are coupled to the source select line SSL1 or SSL2. A group of memory cells included in cell strings ST arranged in the X direction and coupled to the same word line may be referred to as a page PG. In the memory device, a program operation or a read operation on a selected memory block may be performed on a page PG basis.

The drain select line may be divided into or comprise a first drain select line DSL1 and a second drain select line DSL2. The drain select lines DSL1 and DSL2 extend in the X direction, and are arranged in parallel along the Y direction. The cell strings ST are divided into first cell strings ST1 coupled to the first drain select line DSL1 and second cell strings ST2 coupled to the second drain select line DSL2.

During a program operation, when the first drain select line DSL1 is selected and the second drain select line DSL2 is unselected, a first memory cell group 31 corresponding to the first drain select line DSL1 is the target of the program operation, and a second memory cell group 32 corresponding to the second drain select line DSL2 is excluded as the target of the program operation. Thus, when the first drain select line DSL1 is selected, memory cells included in the first memory cell group 31 are selected. When the second drain select line DSL2 is unselected, memory cells included in the second memory cell group 32 are unselected. When the first drain select line DSL1 is unselected, the memory cells included in the first memory cell group 31 are unselected. When the second drain select line DSL2 is selected, the memory cells included in the second memory cell group 32 are selected.

During the program operation, when the first drain select line DSL1 is selected, a turn-on voltage is applied to the first drain select line DSL1, whereas when the first drain select line DSL1 is unselected, a turn-off voltage is applied to the first drain select line DSL1. The turn-on voltage is a voltage that turns on drain select transistors coupled to the first drain select line DSL1, and the turn-off voltage is a voltage that turns off the drain select transistors coupled to the first drain select line DSL1.

During the program operation, when the turn-on voltage is applied to the first drain select line DSL1 and the turn-off voltage is applied to the second drain select line DSL2, the threshold voltages of the memory cells included in the second memory cell group 32 are maintained in a previous state while the memory cells included in the first memory cell group 31 are programmed.

In order to maintain the threshold voltages of the memory cells included in the second memory cell group 32, a channel boosting operation that increases a channel voltage is performed on the second cell strings ST2.

Because a selected word line to which a program voltage is applied is coupled in common with the first memory cell group 31 and the second memory cell group 32, a program disturb DS may occur in the second memory cell group 32 adjacent to the first memory cell group 31 in the Y direction. Program disturb refers to a condition or phenomenon where the threshold voltages of unselected memory cells increase.

In order to reduce program disturb, the present embodiment discloses a program operation simultaneously performed on the first cell strings ST1 that are coupled to the first drain select line DSL1 and on the second cell strings ST2 that are coupled to the second drain select line DSL2.

FIG. 4 is a flowchart illustrating a program operation method of a memory device according to the present disclosure. The method is performed, for example, by the various components of the peripheral circuit 180.

Referring to FIG. 4, when a program operation on a selected memory block starts, the channels of plugs coupled to different select transistors among plugs included in the selected memory block are precharged S41. The different select transistors refer to transistors coupled to different select lines. For example, the different select transistors include drain select transistors coupled to a first drain select line and drain select transistors coupled to a second drain select line. When a precharge voltage is applied through bit lines and a turn-on voltage is applied to the first drain select line DSL1 and the second drain select line DSL2, the precharge voltage is applied to the channels of the plugs coupled to the first drain select line DSL1 and the second drain select line DSL2. The precharge voltage may be a positive voltage higher than 0 V. Because all of the drain select transistors coupled to the first drain select line DSL1 and the second drain select line DSL2 are turned on, the precharge voltage may be simultaneously applied to the channels of the plugs coupled to the first drain select line DSL1 and the second drain select line DSL2.

When the channels of the plugs coupled to the different select transistors are precharged at the precharge voltage, each plug is classified S42 as either a selected plug or an unselected plug.

The selected plug and the unselected plug are classified depending on the data input to page buffers. For example, a plug coupled to a page buffer to which data ‘0’ is input is classified as a selected plug, and a plug coupled to a page buffer to which data ‘1’ is input is classified as an unselected plug.

When at least one of the plugs coupled to the different select transistors is determined S42 to be an unselected plug, a program-enable voltage is applied S43 to the channel of the selected plugs and a program-inhibit voltage is applied S43 to the channel of the unselected plugs. For example, the page buffer to which data ‘0’ is input applies the program-enable voltage to the corresponding bit line, and the page buffer to which data ‘1’ is input applies the program-inhibit voltage to the corresponding bit line. The program-enable voltage may be 0 V or a positive voltage lower than the program-inhibit voltage. The program-inhibit voltage may be a positive voltage higher than the program-enable voltage.

When all of the plugs coupled to different select transistors are determined S42 to be selected plugs, the program-enable voltage is applied S44 to the channels of the selected plugs.

When all of the plugs coupled to different select transistors are determined S42 to be unselected plugs, the program-inhibit voltage is applied S45 to the channels of the unselected plugs.

Phrased in a different way, when a plug is an unselected plug, the memory cells of the unselected plug are unselected memory cells, and when a plug is a selected plug, the memory cells of the unselected plug are selected memory cells. When selected memory cells are included in a first plug and in a second plug, the program-enable voltage is applied to the first channel of the first plug and to the second channel of the second plug. When selected memory cells are included in a first plug and selected memory cells are not included in a second plug when the second plug is an unselected plug, the program-enable voltage is applied to the first channel of the first plug, and the program-inhibit voltage is applied to the second channel of the second plug. When selected memory cells are not included in the first plug and not included in the second plug when the first plug and the second plug are unselected plugs, the program-inhibit voltage is applied to the first channel of the first plug and the second channel of the second plug. When the selected memory cells are included each of a plurality of plugs, the program voltage is applied to a channel of each of the plurality of plugs. When the selected memory cells are not included in at least one of a plurality of plugs, the program voltage is applied to a channel of each plug in which a selected memory cell is included among the plurality of plugs; and the program-inhibit voltage is applied to a channel of a plug in which a selected memory cell is not included among the plurality of plugs. When the selected memory cells are not included in any of a plurality of plugs, the program-inhibit voltage is applied to each channel of the plurality of plugs.

After the program-enable and program-inhibit voltages are applied S43, S44, S45, a pass voltage is applied to unselected word lines and a program voltage is applied to a selected word line. Alternatively, after the pass voltage is applied to the unselected word lines and the selected word line, the program voltage may be applied to the selected word line. The pass voltage may be a voltage capable of turning on the memory cells and may be adjusted to various levels. The pass voltage may be at different levels depending on the locations of the unselected word lines. When the pass voltage is applied to the selected word line, the pass voltage applied to the selected word line may have a level different than the level of the pass voltage applied to the unselected word lines. The program voltage is a voltage capable of increasing the threshold voltages of the memory cells.

When the program voltage is applied to the selected word line for a predetermined period of time, a verify operation is performed S47. The verify operation includes determining whether the threshold voltages of the selected memory cells achieved or are increased to a target voltage. During the verify operation, a verify voltage is applied to the selected word line. The verify voltage may be a positive voltage lower than the program voltage and may be changed depending on the target voltage.

When the result of the verify operation performed is determined S47 as a pass, the program operation on the selected page is terminated or ended. When the result of the verify operation performed is determined S47 as a fail, the program voltage is increased S48 to further perform the program operation on the selected page. When the program voltage is increased by a preset step voltage, the method is performed again beginning with the precharging S41 process. The method of FIG. 4 may be repeated until the result of the verify operation is determined S47 as a pass.

Example structures of the memory block on which the method of FIG. 4 is performed are described with respect to various embodiments.

FIG. 5 is a perspective view illustrating the structure of a memory block according to a first embodiment of the present disclosure.

Referring to FIG. 5, a portion of a memory block including word lines and drain select lines is illustrated. Word lines WL(n−3) to WLn are stacked, and the first drain select line DSL1 and the second drain select line DSL2 are disposed over the n-th word line WLn located uppermost among the word lines. The word lines WL(n−3) to WLn are spaced apart from the first drain select line DSL1 and the second drain select lined DSL2. The first drain select line DSL1 is spaced apart from the second drain select line DSL2 by a division region DV extending in an X direction.

The first drain select line DSL1 and the second drain select line DSL2 contact plugs arranged along a first row R1 and a second row R2. For example, first plugs P1 arranged along the first row R1 and third plugs P3 arranged along the second row R2 contact the first drain select line DSL1, and second plugs P2 arranged along the first row R1 and fourth plugs P4 arranged along the second row R2 contact the second drain select line DSL2. The first plugs P1 and the third plugs P3 penetrate the first drain select line DSL1 and the word lines WL(n−3) to WLn. The second plugs P2 and the fourth plugs P4 penetrate the second drain select line DSL2 and the word lines WL(n−3) to WLn.

In the remaining region of the memory block, not illustrated in FIG. 5, the first plugs P1 to fourth plugs P4 penetrate the remaining word lines W1 to WL(n−4) and the source select lines.

The first row R1 of first plugs P1 and the first row R1 of second plugs P2 may be symmetrical to each other with respect to the division region DV, and the second row R2 of third plugs P3 and the second row R2 of fourth plugs P4 may be symmetrical to each other with respect to the division region DV.

The plugs P1 to P4 may have the same structure. Referring to a cross-section in a plane 51 of any plug, for example, the first plug P1 among the plugs P1 to P4, the first plug P1 includes a core pillar CP, a channel layer CH, a tunnel isolation layer TX, a charge trap layer CTL, and a blocking layer BX that form memory cells or select transistors. The core pillar CP may have a cylindrical shape and may be formed of an insulating material or a conductive material. The channel layer CH may have a cylindrical shape enclosing or surrounding the outer side surface of the core pillar CP and may be formed of polysilicon. The tunnel isolation layer TX may have a cylindrical shape enclosing or surrounding the outer side surface of the channel layer CH and may be formed of an oxide layer. The charge trap layer CTL may have a cylindrical shape enclosing the outer side surface of the tunnel isolation layer TX and may be formed of a nitride layer. The blocking layer BX may have a cylindrical shape enclosing or surrounding the outer side surface of the charge trap layer CTL and may be formed of an oxide layer.

The first bit line BL1 to tenth bit line BL10 are arranged on the first plug P1 to the fourth plug P4. FIG. 5 illustrates a portion of the memory block. The quantity of bit lines is not limited to the quantity of bit lines illustrated in FIG. 5. The bit lines BL1 to BL10 may individually extend along the Y direction and may be spaced apart from each other along the X direction. Two bit lines are arranged on each of the first plug P1 to fourth plug P4, and one of the two bit lines contacts one plug. For example, assuming that the first bit line BL1 and the second bit line BL2 are arranged on the first plug P1 and the second plug P2, the first bit line BL1 contacts the first plug P1, and the second bit line BL2 contacts the second plug P2. The third bit line BL3 and the fourth bit line BL4 are arranged on the third plug P3 and the fourth plug P4, where the third bit line BL3 contacts the third plug P3 and the fourth bit line BL4 contacts the fourth plug P4.

FIG. 6 is a layout view illustrating a connection relationship between a memory block and page buffers according to a first embodiment of the present disclosure.

Referring to FIG. 5 and FIG. 6, the first bit line BL1 to ninth bit line BL9 are coupled to the first page buffer PB1 to the ninth page buffer PB9, respectively. For example, the first bit line BL1, the third bit line BL3, the fifth bit line BL5, the seventh bit line BL7, and the ninth bit line BL9 are coupled to the first page buffer PB1, the third page buffer PB3, the fifth page buffer PB5, the seventh page buffer PB7, and the ninth page buffer PB9, respectively. The second bit line BL2, the fourth bit line BL4, the sixth bit line BL6, and the eighth bit line BL8 are coupled to the second page buffer PB2, the fourth page buffer PB4, the sixth page buffer PB6, and the eighth page buffer PB8, respectively.

One of the first plugs P1 contacts a different bit line of the first bit line BL1, the fifth bit line BL5, and the ninth bit line BL9, each contact made through a different one of the contacts CT. A contact CT is, for example an electrical conductor, such as between a channel layer CH of a plug and a bit line. One of the second plugs P2 contacts the second bit line BL2 through one of the contacts CT, and a different one of the second plugs P2 contacts the sixth bit line BL6 through a different one of the contacts CT. One of the third plugs P3 contacts the third bit line BL3 through one of the contacts CT, and a different one of the third plugs P3 contacts the seventh bit line BL7 through a different one of the contacts CT. One of the fourth plugs P4 contacts the fourth bit line BL4 through one of the contacts CT, and a different one of the fourth plugs P4 contacts the eighth bit line BL8 through a different one of the contacts CT.

When a turn-on voltage is applied to the first drain select line DSL1, the first plugs P1 are coupled to the first page buffer PB1, the fifth page buffer PB5, and the ninth page buffer PB9 through the contacts CT and the first bit line BL1, the fifth bit line BL5, and the ninth bit line BL9, respectively, and the third plugs P3 are coupled to the third page buffer PB7 and the seventh page buffer PB7 through the contacts CT and the third bit line BL7 and the seventh bit line BL7, respectively.

When the turn-on voltage is applied to the second drain select line DSL2, the second plugs P2 are coupled to the second page buffer PB2 and the sixth page buffer PB6 through the contacts CT and the second bit line BL2 and the sixth bit line BL6, respectively, and the fourth plugs P4 are coupled to the fourth page buffer PB4 and the eighth page buffer PB8 through the contacts CT and the fourth bit line BL4 and the eighth bit line BL8, respectively.

When the turn-on voltage is simultaneously applied to the first drain select line DSL1 and the second drain select line DSL2, the first plugs P1 are simultaneously and electrically connected to the first page buffer PB1, the fifth page buffer PB5, and the ninth page buffer PB9, the second plugs P2 are simultaneously and electrically connected to the second page buffer PB2 and the sixth page buffer PB6, the third plugs P3 are simultaneously and electrically connected to the third page buffer PB3 and the seventh page buffer PB7, and the fourth plugs P4 are simultaneously and electrically connected to the fourth page buffer PB4 and the eighth page buffer PB8.

Therefore, during the program operation, the program operation may be simultaneously performed on the first plugs P1 and the third plugs P3 contacting the first drain select line DSL1 and on the second plugs P2 and the fourth plugs P4 contacting the second drain select line DSL2.

For example, when the turn-on voltage is simultaneously applied to the first drain select line DSL1 and the second drain select line DSL2, the plugs P1 to P4 are simultaneously activated. Among the memory cells included in the plugs P1 to P4, the selected memory cells are classified as selected memory cells or unselected memory cells depending on the data input to the page buffers PB1 to PB9.

Therefore, each of the activated plugs P1 to P4 is classified as a selected plug or an unselected plug depending on the data input to the page buffers PB1 to PB9. For example, a plug corresponding to a page buffer to which data ‘0’ is input is a selected plug, and a plug corresponding to a page buffer to which data ‘1’ is input is an unselected plug. Classifying each plug as a selected plug or an unselected plug depends on the data input to the corresponding page buffer, and the classifications may be changed. For example, a plug corresponding to a page buffer to which data ‘0’ is input may be an unselected plug, and a plug corresponding to a page buffer to which data ‘1’ is input may be a selected plug depending on the settings of the memory device. In embodiments described below, an unselected plug corresponds to data ‘1’ and a selected plug corresponds to data ‘0’.

During a program operation, all of the plugs P1 to P4 contacting the first drain select line DSL1 and the second drain select line DSL2 are activated, and selected plugs and unselected plugs among the activated plugs are classified as either selected or unselected. Therefore, some of the first plugs P1 and the third plugs P3 contacting the first drain select line DSL1 are selected plugs and the remaining plugs are unselected plugs, depending on data input to the page buffers PB1, PB3, PB5, PB7, and PB9. Some of the plugs P2 and P4 contacting the second drain select line DSL2 are selected plugs and the remaining plugs are unselected plugs, depending on data input to the page buffers PB2, PB4, PB6, and PB8.

As a result, during the program operation, when the activated plugs and the deactivated plugs are separated by the division region between the first drain select line DSL1 and the second drain select line DSL2, all deactivated plugs are unselected plugs. Therefore, a potential difference increases between the activated plugs and the deactivated plugs, and program disturb may occur in some of the deactivated plugs.

During the program operation, when all plugs contacting the first drain select line DSL1 and the second drain select line DSL2 are activated, the selected plugs and the unselected plugs are arranged regardless of the first drain select line DSL1 and the second drain select line DSL2, thus decreasing the potential difference between the plugs, with the result that program disturb may be mitigated.

Because the plugs contacting the first drain select line DSL1 and the second drain select line DSL2, may be selected plugs or unselected plugs depending on the data input to the page buffers, program operations for various examples are described.

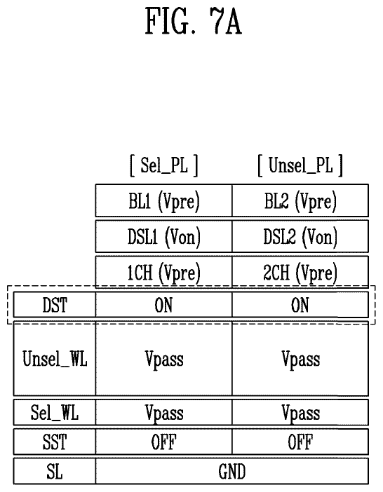

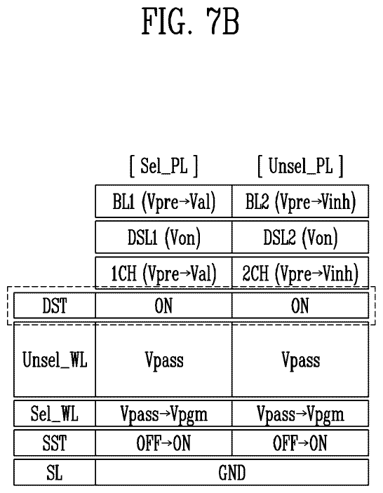

FIG. 7A and FIG. 7B are tables including voltages and transistor states during a program operation according to a first embodiment of the present disclosure when at least one of plugs is unselected.

Referring to FIG. 6 and FIG. 7A, in this example, a plug contacting the first drain select line DSL1 is a selected plug Sel_PL coupled to the first bit line BL1 and a plug contacting the second drain select line DSL2 is an unselected plug Unsel_PL coupled to the second bit line BL2. For example, the selected plug Sel_PL is a plug coupled to a bit line to which a program-enable voltage is applied. The bit line to which the program-enable voltage is applied is a bit line coupled to a page buffer to which data ‘0’ is input. The unselected plug Unsel_PL is a plug coupled to a bit line to which a program-inhibit voltage is applied. The bit line to which the program-inhibit voltage is applied is a bit line coupled to a page buffer to which data ‘1’ is input.

A ground voltage GND is applied to a source line SL, and all of the source select transistors SST are turned off. As a result, the selected plug Sel_PL and the unselected plug Unsel_PL are not coupled to the source line SL. A pass voltage Vpass is applied to unselected word lines Unsel_WL and a selected word line Sel_WL. The pass voltage Vpass is a positive voltage capable of turning on the memory cells. The level of the pass voltage Vpass may be one of various different values higher than 0 V. A turn-on voltage Von is applied to the first drain select line DSL1 and the second drain select line DSL2. Due to the turn-on voltage Von applied to the first drain select line DSL1 and the second drain select line DSL2, the drain select transistors DST coupled to the select lines DSL1 and DSL2 are turned on.

A precharge voltage Vpre is applied to the first bit line BL1 and the second bit line BL2. The precharge voltage Vpre may be a positive voltage higher than 0 V.

Because all of the drain select transistors DST coupled to the drain select lines DSL1 and DSL2 are turned on, the precharge voltage Vpre applied to the first bit line BL1 is applied to the first channel 1CH of the selected plug Sel_PL and the precharge voltage Vpre applied to the second bit line BL2 is applied to the second channel 2CH of the unselected plug Unsel_PL. Therefore, the channels 1CH and 2CH may be simultaneously precharged to the precharge voltage Vpre.

Referring to FIG. 6 and FIG. 7B, after the first channel 1CH and the second channel 2CH are precharged, as described with reference to FIG. 7A, the program-enable voltage Val is applied to the first bit line BL1, and the program-inhibit voltage Vinh is applied to the second bit line BL2, depending on data of the page buffers coupled to the bit lines BL1 and BL2. In this example, data input to the page buffer coupled to the first bit line BL1 is ‘0’ and data input to the page buffer coupled to the second bit line BL2 is ‘1’. When data ‘0’ is data that increases the threshold voltage of a memory cell and data ‘1’ is data that maintains the threshold voltage of the memory cell in a previous state, the page buffer to which data ‘0’ is input outputs the program-enable voltage Val through the corresponding bit line, and the page buffer to which data ‘1’ is input outputs the program-inhibit voltage Vinh through the corresponding bit line. Therefore, as described with reference to FIG. 7A, the plug to which the program-enable voltage Val is applied is a selected plug Sel_PL, and the plug to which the program-inhibit voltage Vinh is applied is an unselected plug Unsel_PL. The program-inhibit voltage Vinh may be a positive voltage higher than the program-enable voltage Val.

Because the drain select transistors DST coupled to the drain select lines DSL1 and DSL2 are turned on, the program-enable voltage Val applied to the first bit line BL1 is transferred to the first channel 1CH of the selected plug Sel_PL, and the program-inhibit voltage Vinh applied to the second bit line BL2 is transferred to the second channel 2CH of the unselected plug Unsel_PL. Therefore, the voltage of the first channel 1CH decreases to the program-enable voltage Val, and the voltage of the second channel 2CH increases to the program-inhibit voltage Vinh. Because the source select transistors SST are turned on, the voltage of the first channel 1CH is at a voltage level lower than the voltage level of the program-enable voltage Val, and the voltage of the second channel 2CH is at a voltage level lower than the voltage level of the program-inhibit voltage Vinh.

In order to increase the threshold voltage of a selected memory cell among memory cells coupled to the selected word line Sel_WL, the pass voltage Vpass is applied to the unselected word lines Unsel_WL, and a program voltage Vpgm is applied to the selected word line Sel_WL. A memory cell coupled to the selected word line Sel_WL among the memory cells included in the selected plugs Sel_PL is the selected memory cell, and a memory cell coupled to the selected word line Sel_WL among the memory cells included in the unselected plugs Unsel_PL is an unselected memory cell.

The turn-on voltage is applied to the source select lines, thus the source select transistors SST are turned on. Therefore, the first channel 1CH of the selected plug Sel_PL and the second channel 2CH of the unselected plug Unsel_PL are electrically connected to the source line SL. As a result, the voltage of the first channel 1CH is lower than or equal to the program-enable voltage Val, and the voltage of the second channel 2CH is lower than or equal to the program-inhibit voltage Vinh.

Although not illustrated in the drawings, a positive voltage higher than 0 V may be applied to the source line SL and a turn-off voltage may be applied to the source select lines to prevent the channel voltage of the unselected plugs Unsel_PL from decreasing in other embodiments.

The selected memory cell of the selected plug Sel_PL is programmed due to the voltage difference between the program voltage Vpgm applied to the selected word line Sel_WL and the program-enable voltage Val applied to the first channel 1CH. For example, when a voltage difference enabling programming is a reference voltage difference, the voltage difference between the gate and the channel of the selected memory cell is equal to or higher than the reference voltage difference.

The unselected memory cell of the unselected plug Unsel_PL is program-inhibited due to the voltage difference between the program voltage Vpgm applied to the selected word line Sel_WL and the program-inhibit voltage Vinh applied to the second channel 2CH. For example, the voltage difference between the gate and the channel of the unselected memory cell is lower than the reference voltage difference.

Even when the voltage of the second channel 2CH is lower than the program-inhibit voltage Vinh, the level of the program-inhibit voltage Vinh is sufficiently high to prevent the threshold voltages of unselected memory cells from increasing, and the program-inhibit voltage Vinh continues to be supplied to the second channel 2CH through the second bit line BL2. Therefore, the memory cell coupled to the selected word line Sel_WL among the memory cells included in the unselected plug Unsel_PL is program-inhibited.

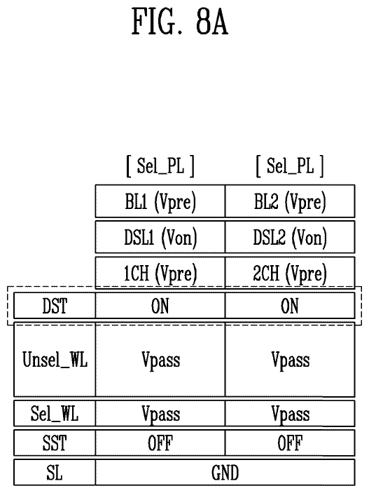

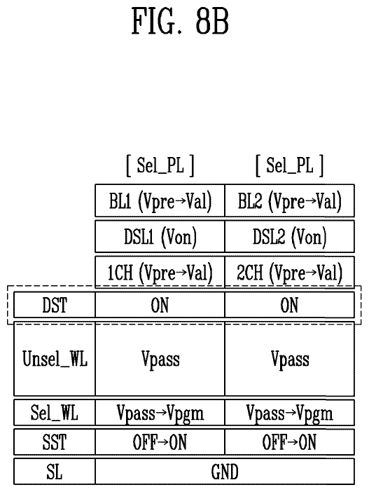

FIG. 8A and FIG. 8B are tables including voltages and transistor states during a program operation according to a first embodiment of the present disclosure when all plugs are selected plugs.

Referring to FIG. 6 and FIG. 8A, in this example, a plug contacting the first drain select line DSL1 is a selected plug Sel_PL coupled to the first bit line BL1 and a plug contacting the second drain select line DSL2 is a selected plug Sel_PL coupled to the second bit line BL2. For example, the selected plug Sel_PL is a plug coupled to a bit line to which a program-enable voltage is applied. The bit line to which the program-enable voltage is applied is a bit line coupled to a page buffer to which data ‘0’ is input.

A ground voltage GND is applied to the source line SL, and all of the source select transistors SST are turned off. As a result, the selected plugs Sel_PL are not coupled to the source line SL. A pass voltage Vpass is applied to unselected word lines Unsel_WL and a selected word line Sel_WL. The pass voltage Vpass is a positive voltage capable of turning on the memory cells. A turn-on voltage Von is applied to the drain select lines DSL1 and DSL2. Due to the turn-on voltage Von applied to the drain select lines DSL1 and DSL2, the drain select transistors DST coupled to the drain select lines DSL1 and DSL2 are turned on.

A precharge voltage Vpre is applied to the first bit line BL1 and the second bit line BL2. The precharge voltage Vpre may be a positive voltage higher than 0 V.

Because all of the drain select transistors DST coupled to the drain select lines DSL1 and DSL2 are turned on, the precharge voltage Vpre applied to the first bit line BL1 is applied to the first channel 1CH of the selected plug Sel_PL and the precharge voltage Vpre applied to the second bit line BL2 is applied to the second channel 2CH of the selected plug Sel_PL. Therefore, the channels 1CH and 2CH may be simultaneously precharged to the precharge voltage Vpre.

Referring to FIG. 6 and FIG. 8B, after the channels 1CH and 2CH are precharged as described with reference to FIG. 8A, the program-enable voltage Val is applied to the first bit line BL1 and the second bit line BL2 depending on data of the page buffers coupled to the first bit line BL1 and the second bit line BL2. In this example, both data input to the page buffers coupled to the first bit line BL1 and the second bit line BL2 are ‘0’. When data ‘0’ is data that increases the threshold voltage of a memory cell, the page buffer to which data ‘0’ is input outputs the program-enable voltage Val through the corresponding bit line.

Because the drain select transistors DST coupled to the drain select lines DSL1 and DSL2 are turned on, the program-enable voltage Val applied to the bit lines BL1 and BL2 is transferred to the channels 1CH and 2CH of the selected plugs Sel_PL. Therefore, the voltages of the channels 1CH and 2CH decrease to the program-enable voltage Val. Because the source select transistors SST are turned on, the voltages of the channels 1CH and 2CH are at voltage levels lower than the voltage level of the program-enable voltage Val.

In order to increase the threshold voltage of a selected memory cell among memory cells coupled to the selected word line Sel_WL, the pass voltage Vpass is applied to the unselected word lines Unsel_WL, and a program voltage Vpgm is applied to the selected word line Sel_WL.

The turn-on voltage is applied to the source select lines, thus the source select transistors SST are turned on. Therefore, the first channel 1CH of the selected plug Sel_PL and the second channel 2CH of the selected plug Sel_PL are electrically connected to the source line SL. As a result, the voltages of the channels 1CH and 2CH are lower than or equal to the program-enable voltage Val.

The selected memory cells of the selected plugs Sel_PL are programmed due to the voltage difference between the program voltage Vpgm applied to the selected word line Sel_WL and the program-enable voltage Val applied to the channels 1CH and 2CH. For example, when a voltage difference enabling programming is a reference voltage difference, the voltage difference between the gate and the channel of the selected memory cell is equal to or higher than the reference voltage difference.

Because all of memory cells coupled to the selected word line Sel_WL among the memory cells included in the selected plugs Sel_PL are selected memory cells, selected memory cells that correspond to different drain select lines DSL1 and DSL2 and that are adjacent to each other may be simultaneously programmed.

In this way, the memory cells adjacent to each other are simultaneously programmed, whereby a voltage difference decreases between the adjacent memory cells. Accordingly, program disturb may be prevented from occurring between the adjacent memory cells.

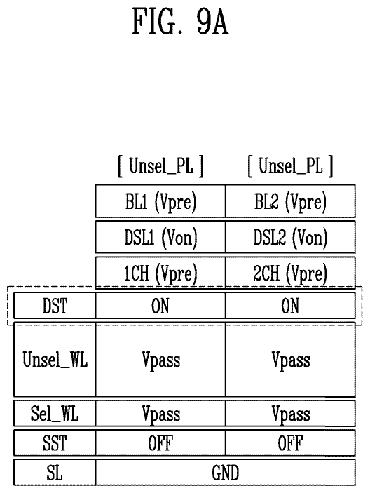

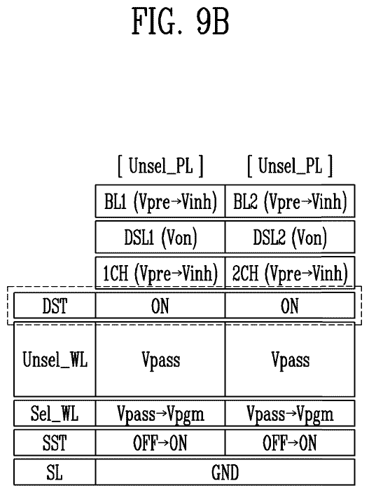

FIG. 9A and FIG. 9B are tables including voltages and transistor states during a program operation according to a first embodiment of the present disclosure when all plugs are unselected plugs.

Referring to FIG. 6 and FIG. 9A, in this example, a plug contacting the first drain select line DSL1 is an unselected plug Unsel_PL coupled to the first bit line BL1 and a plug contacting the second drain select line DSL2 is an unselected plug Unsel_PL coupled to the second bit line BL2. For example, the unselected plug Unsel_PL is a plug coupled to a bit line to which a program-inhibit voltage is applied. The bit line to which the program-inhibit voltage is applied is a bit line coupled to a page buffer to which data ‘1’ is input.

A ground voltage GND is applied to a source line SL, and all of the source select transistors SST are turned off. As a result, the unselected plugs Unsel_PL are not coupled to the source line SL. A pass voltage Vpass is applied to unselected word lines Unsel_WL and a selected word line Sel_WL. The pass voltage Vpass is a positive voltage capable of turning on the memory cells. A turn-on voltage Von is applied to the first drain select line DSL1 and the second drain select line DSL2. Due to the turn-on voltage Von applied to the first drain select line DSL1 and the second drain select line DSL2, the drain select transistors DST coupled to the drain select lines DSL1 and DSL2 are turned on.

A precharge voltage Vpre is applied to the first applied to the first bit line BL1 and the second bit line BL2. The precharge voltage Vpre may be a positive voltage higher than 0 V.

Because all of the drain select transistors DST coupled to the drain select lines DSL1 and DSL2 are turned on, the precharge voltage Vpre applied to the first bit line BL1 is applied to the first channel 1CH of the unselected plug Unsel_PL and the precharge voltage Vpre applied to the second bit line BL2 is applied to the second channel 2CH of the unselected plug Unsel_PL. Therefore, the channels 1CH and 2CH may be simultaneously precharged to the precharge voltage Vpre.

Referring to FIG. 6 and FIG. 9B, after the first channel 1CH and the second channel 2CH are precharged as described with reference to FIG. 9A, the program-inhibit voltage Vinh is applied to the bit lines BL1 and BL2 depending on data of the page buffers coupled to the bit lines BL1 and BL2. In this example, data input to the page buffers coupled to the bit lines BL1 and BL2 are ‘1’. When data ‘1’ is data that maintains the threshold voltage of a memory cell in a previous state, the page buffer to which data ‘1’ is input outputs the program-inhibit Vinh through the corresponding bit line. Therefore, as described with reference to FIG. 9A, the plugs to which the program-inhibit voltage Vinh is applied are the unselected plug Unsel_PL.

Because the drain select transistors DST coupled to the drain select lines DSL1 and DSL2 are turned on, the program-inhibit voltage Vinh applied to the bit lines BL1 and BL2 is transferred to the first channel 1CH and the second channel 2CH of the unselected plugs Unsel_PL. Therefore, the voltages of the channels 1CH and 2CH increases to the program-inhibit voltage Vinh. Because the source select transistors SST are turned on, the voltages of the channels 1CH and 2CH are at voltage levels lower than the voltage level of the program-inhibit voltage Vinh.

In order to increase the threshold voltage of a selected memory cell among memory cells coupled to the selected word line Sel_WL, the pass voltage Vpass is applied to the unselected word lines Unsel_WL, and a program voltage Vpgm is applied to the selected word line Sel_WL. Among the memory cells included in the unselected plugs Unsel_PL, a memory cell coupled to the selected word line Sel_WL is an unselected memory cell.

The turn-on voltage is applied to the source select lines, thus the source select transistors SST are turned on. Therefore, the channels 1CH and 2CH are electrically connected to the source line SL. As a result, the voltages of the channels 1CH and 2CH are lower than or equal to the program-inhibit voltage Vinh.

Although not illustrated in the drawings, a positive voltage higher than 0 V may be applied to the source line SL and a turn-off voltage may be applied to the source select lines to prevent the channel voltages of the unselected plugs Unsel_PL from decreasing in other embodiments.

The unselected memory cell of the unselected plug Unsel_PL is program-inhibited due to the voltage difference between the program voltage Vpgm applied to the selected word line Sel_WL and the program-inhibit voltage Vinh applied to the first channel 1CH and the second channel 2CH. For example, the voltage difference between the gate and the channel of the unselected memory cell is lower than the reference voltage difference. For example, when a voltage difference enabling programming is a reference voltage difference, the voltage difference between the gate and the channel of the unselected memory cell is lower than the reference voltage difference.

Even when the voltages of the channels 1CH and 2CH are lower than the program-inhibit voltage Vinh, the level of the program-inhibit voltage Vinh is sufficiently high to prevent the threshold voltages of unselected memory cells from increasing, and the program-inhibit voltage Vinh continues to be supplied to the channels 1CH and 2CH through the bit lines BL1 and BL2. Accordingly, the memory cells coupled to the selected word line Sel_WL among the memory cells included in the unselected plugs Unsel_PL are program-inhibited while the program operation is performed on the selected memory cells coupled to the selected word line Sel_WL.

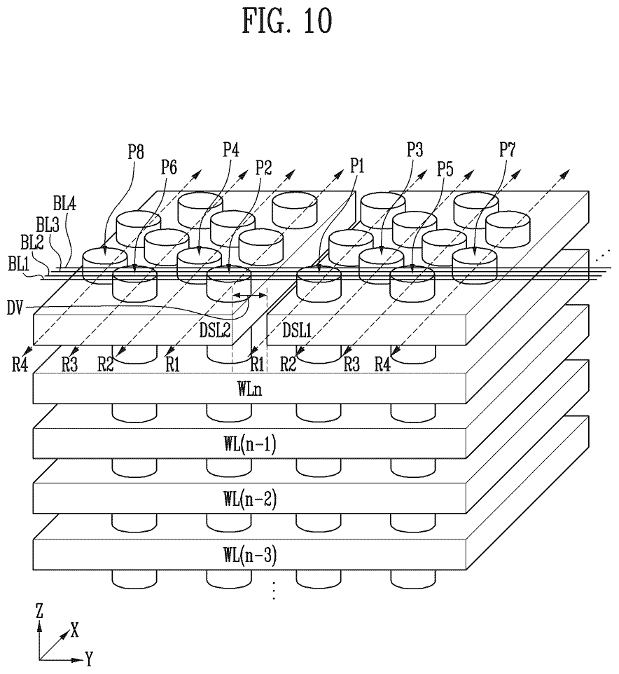

FIG. 10 is a perspective view illustrating the structure of a memory block according to a second embodiment of the present disclosure.

Referring to FIG. 10, in the memory block according to the second embodiment, plugs arranged along the first R1 to the fourth row R4 contact the drain select lines DSL1 and DSL2. For example, the first plugs P1 arranged along the first row R1, the third plugs P3 arranged along the second row R2, the fifth plugs P5 arranged along the third row R3, and the seventh plugs P7 arranged along the fourth row R4 contact the first drain select line DSL1. The second plugs P2 arranged along the first row R1, the fourth plugs P4 arranged along the second row R2, the sixth plugs P6 arranged along the third row R3, and the eighth plugs P8 arranged along the fourth row R4 contact the second drain select line DSL2. The first plugs P1, the third plugs P3, the fifth plugs P5, and the seventh plugs P7 penetrate the first drain select line DSL1 and the word lines WL(n−3) to WLn. The second plugs P2, the fourth plugs P4, the sixth plugs P6, and the eighth plugs P8 penetrate the second drain select line DSL2 and the word lines WL(n−3) to WLn.

In the remaining region of the memory block, not illustrated in FIG. 10, the plugs P1 to P8 penetrate the remaining word lines W1 to WL(n−4) and the source select lines.

The first row R1 of first plugs P1 and the first row R1 of second plugs P2 may be symmetrical to each other with respect to the division region DV, and the second row R2 of third plugs P3 and the second row R2 of fourth plugs P4 may be symmetrical to each other with respect to the division region DV, the third row R3 of fifth plugs P5 and the third row R3 of sixth plugs P6 may be symmetrical to each other with respect to the division region DV, and the fourth row R4 of seventh plugs P7 and the fourth row R4 of eighth plugs P8 may be symmetrical to each other with respect to the division region DV.

The plugs P1 to P8 may have the same structure. The planar structure or cross section of each of the plugs P1 to P8 is similar to the structure described with reference to FIG. 5.

A plurality of bit lines BL1 to BL4 plugs P1 to P8. FIG. 10 illustrates a portion of the memory block. The quantity of bit lines is not limited to the quantity of bit lines illustrated in FIG. 10. Only four bit lines, for example, bit lines BL1 to BL4 are illustrated for convenience of description. The bit lines BL1 to BL4 extend along the Y direction and are spaced apart from each other along the X direction. The four bit lines are arranged on each of the plugs P1 to P8, and each of the four bit lines contacts one plug. For example, assuming that the bit lines BL1 to BL4 are arranged on the plugs P1, P2, P5, and P6, the first bit line BL1 contacts one of the first plugs P1, the second bit line BL2 contacts one of the second plugs P2, the third bit line BL3 contacts one of the fifth plug P5, and the fourth bit line BL4 contacts one of the sixth plugs P6.

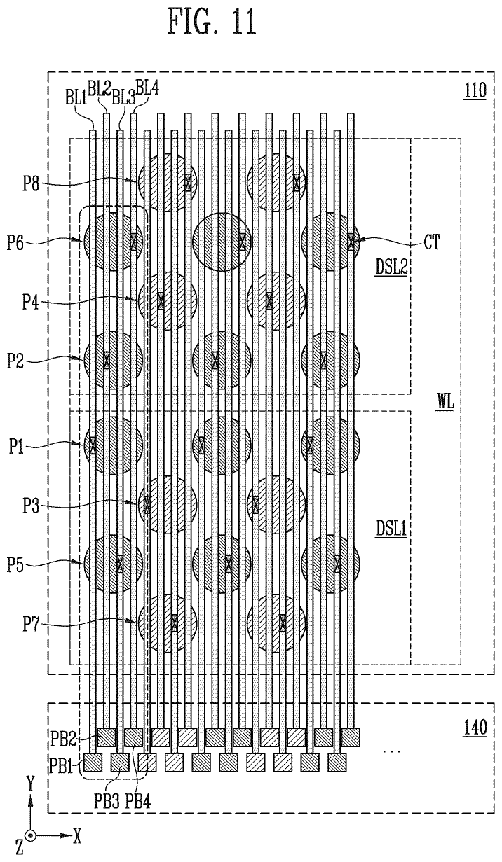

FIG. 11 is a layout view illustrating a connection relationship between a memory block and page buffers according to a second embodiment of the present disclosure.

Referring to FIG. 10 and FIG. 11, the first bit line BL1 to the fourth bit line BL4 are coupled to first page buffer PB1 to the fourth page buffer PB4, respectively.

The first plug P1, the second plug P2, the fifth plug P5, and the sixth plug P6 contacting any of the bit lines BL1 to BL4 are described.

The first plug P1 contacts the first bit line BL1 through a contact CT. The second plug P2 contacts the second bit line BL2 through a contact CT. The fifth plug P5 contacts the third bit line BL3 through a contact CT. The sixth plug P6 contacts the fourth bit line BL4 through a contact CT.

When a turn-on voltage is applied to the first drain select line DSL1, the first plug P1 is electrically connected to the first page buffer PB1 through a contact CT and the first bit line BL1, and the fifth plug P5 is electrically connected to the third page buffer PB3 through a contact CT and the third bit line BL3.

When a turn-on voltage is applied to the second drain select line DSL2, the second plug P2 is electrically connected to the second page buffer PB2 through a contact CT and the second bit line BL2, and the sixth plug P6 is electrically connected to the fourth page buffer PB4 through a contact CT and the fourth bit line BL4.

When the turn-on voltage is simultaneously applied to the first drain select line DSL1 and the second drain select line DSL2, the first plug P1 is electrically connected to the first page buffer PB1 at the same time that the second plug P2 is electrically connected to the second page buffer PB2.

During a program operation, even though the first plug P1 and the second plug P2 are simultaneously selected, the first plug P1 is electrically connected to the first page buffer PB1 and the second plug P2 is electrically connected to the second page buffer PB2, thus the program operation may be simultaneously performed on the first plug P1 and the second plug P2.

Because the plugs contacting the drain select lines DSL1 and DSL2 may be selected plugs or unselected plugs depending on the data input to the page buffers, program operations for various examples are described.

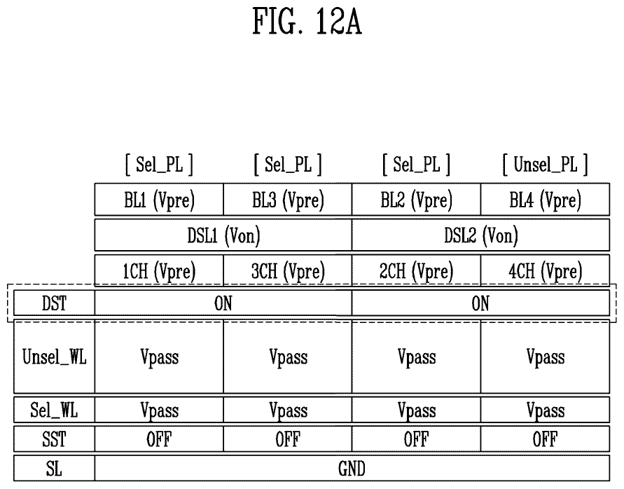

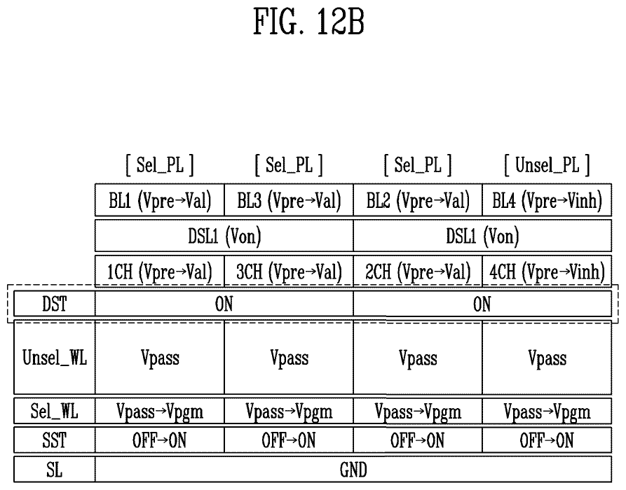

FIG. 12A and FIG. 12B are tables including voltages and transistor states during a program operation according to a second embodiment of the present disclosure when at least one of plugs is unselected.

Referring to FIG. 11 and FIG. 12A, in this example, plugs contacting the first drain select line DSL1 are selected plugs Sel_PL coupled to the bit lines BL1 and BL3 and plugs contacting the second drain select line DSL2 are a selected plug Sel_PL coupled to the second bit line BL2 and an unselected plug Unsel_PL coupled to the fourth bit line BL4. The selected plug Sel_PL is a plug coupled to a bit line to which a program-enable voltage is applied. The bit line to which the program-enable voltage is applied is a bit line coupled to a page buffer to which data ‘0’ is input. The unselected plug Unsel_PL is a plug coupled to a bit line to which a program-inhibit voltage is applied. The bit line to which the program-inhibit voltage is applied is a bit line coupled to a page buffer to which data ‘1’ is input.

A ground voltage GND is applied to a source line SL, and all of the source select transistors SST are turned off. As a result, the selected plugs Sel_PL and the unselected plug Unsel_PL are not coupled to the source line SL. A pass voltage Vpass is applied to unselected word lines Unsel_WL and a selected word line Sel_WL. The pass voltage Vpass is a positive voltage capable of turning on the memory cells. The turn-on voltage Von is applied to the first drain select line DSL1 and the second drain select line DSL2 and may be simultaneously applied to the drain select lines DSL1 and DSL2. Due to the turn-on voltage Von applied to the first drain select line DSL1 and the second drain select line DSL2, the drain select transistors DST coupled to the drain select lines DSL1 and DSL2 are turned on.

A precharge voltage Vpre is applied to the bit lines BL1 to BL4. The precharge voltage Vpre may be a positive voltage higher than 0 V.

Because all of the drain select transistors DST coupled to the drain select lines DSL1 and DSL2 are turned on, the precharge voltage Vpre applied to the bit lines BL1 to BL3 is applied to the channels 1CH to 3CH of the selected plugs Sel_PL, and the precharge voltage Vpre applied to the fourth bit line BL4 is applied to the fourth channel 4CH of the unselected plug Unsel_PL. Therefore, the channels 1CH to 4CH may be simultaneously precharged to the precharge voltage Vpre.

Referring to FIG. 11 and FIG. 12B, after the channels 1CH to 4CH are precharged, as described with reference to FIG. 12A, the program-enable voltage Val is applied to the bit lines BL1 to BL3, and the program-inhibit voltage Vinh is applied to the fourth bit line BL4, depending on data of the page buffers coupled to the bit lines BL1 to BL4. In this example, data input to the page buffers coupled to the bit lines BL1 to BL3 is ‘0’ and data input to the page buffer coupled to the fourth bit line BL4 is ‘1’. When data ‘0’ is data that increases the threshold voltage of a memory cell and data ‘1’ is data that maintains the threshold voltage of the memory cell in a previous state, the page buffer to which data ‘0’ is input outputs the program-enable voltage Val through the corresponding bit line, and the page buffer to which data ‘1’ is input outputs the program-inhibit voltage Vinh through the corresponding bit line. Therefore, as described with reference to FIG. 12A, the plugs to which the program-enable voltage Val is applied are selected plugs Sel_PL, and the plug to which the program-inhibit voltage Vinh is applied is an unselected plug Unsel_PL. The program-inhibit voltage Vinh may be a positive voltage higher than the program-enable voltage Val.

Because the drain select transistors DST coupled to the select lines DSL1 and DSL2 are turned on, the program-enable voltage Val applied to the bit lines BL1 to BL3 is transferred to the channels 1CH to 3CH of the selected plugs Sel_PL, and the program-inhibit voltage Vinh applied to the fourth bit line BL4 is transferred to the fourth channel 4CH of the unselected plug Unsel_PL. Therefore, the voltages of the first channel 1CH, the second channel 2CH, and the third channel 3CH decrease to the program-enable voltage Val, and the voltage of the fourth channel 4CH increases to the program-inhibit voltage Vinh. Because the source select transistors SST are turned on, the voltages of the channels 1CH to 3CH are at a voltage level lower than the voltage level of the program-enable voltage Val, and the voltage of the fourth channel 4CH is at a voltage level lower than the voltage level of the program-inhibit voltage Vinh.

In order to increase the threshold voltages of the selected memory cells among memory cells coupled to the selected word line Sel_WL, the pass voltage Vpass is applied to the unselected word lines Unsel_WL, and a program voltage Vpgm is applied to the selected word line Sel_WL. Memory cells coupled to the selected word line Sel_WL among the memory cells included in the selected plugs Sel_PL are the selected memory cells, and a memory cell coupled to the selected word line Sel_WL among the memory cells included in the unselected plug Unsel_PL is an unselected memory cell.

The turn-on voltage is applied to the source select lines, thus the source select transistors SST are turned on. Therefore, the channels 1CH to 3CH of the selected plugs Sel_PL and the fourth channel 4CH of the unselected plug Unsel_PL are electrically connected to the source line SL. As a result, the voltages of the channels 1CH to 3CH are lower than or equal to the program-enable voltage Val, and the voltage of the fourth channel 4CH is lower than or equal to the program-inhibit voltage Vinh.

The selected memory cells of the selected plugs Sel_PL are programmed due to the voltage difference between the program voltage Vpgm applied to the selected word line Sel_WL and the program-enable voltage Val applied to each of the channels 1CH to 3CH. For example, when a voltage difference enabling programming is a reference voltage difference, the voltage difference between the gate and the channel of each selected memory cell is equal to or higher than the reference voltage difference.

The unselected memory cell of the unselected plug Unsel_PL is program-inhibited due to the voltage difference between the program voltage Vpgm applied to the selected word line Sel_WL and the program-inhibit voltage Vinh applied to the fourth channel 4CH. For example, the voltage difference between the gate and the channel of the unselected memory cell is lower than the reference voltage difference.

Even when the voltage of the fourth channel 4CH is lower than the program-inhibit voltage Vinh, the level of the program-inhibit voltage Vinh is sufficiently high to prevent the threshold voltages of unselected memory cells from increasing, and the program-inhibit voltage Vinh continues to be supplied to the fourth channel 4CH through the fourth bit line BL4. Therefore, the memory cell coupled to the selected word line Sel_WL among the memory cells included in the unselected plug Unsel_PL is program-inhibited.

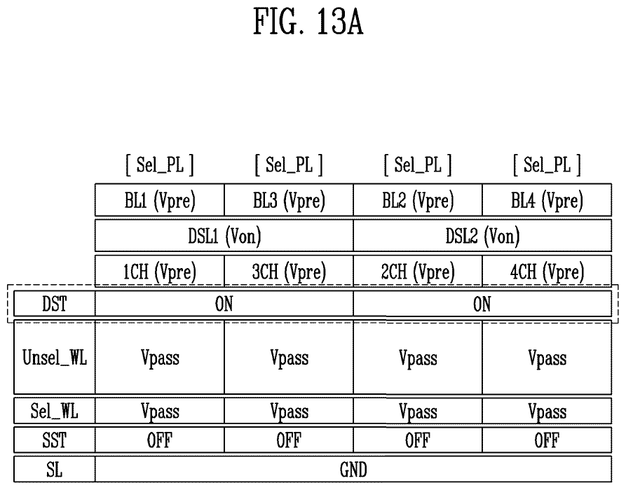

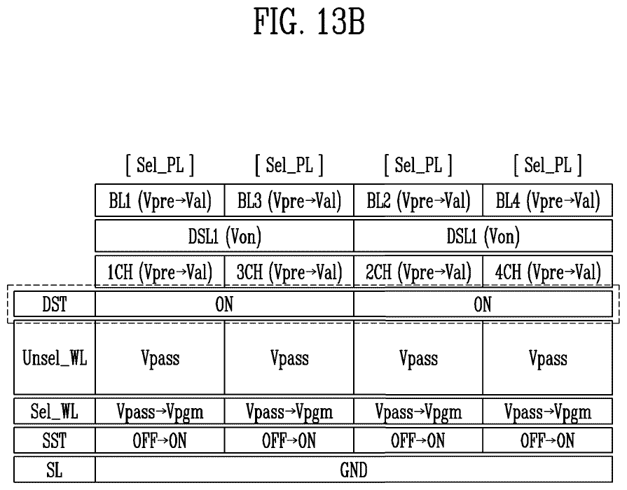

FIG. 13A and FIG. 13B are tables including voltages and transistor states during a program operation according to a second embodiment of the present disclosure when all plugs are selected plugs.

Referring to FIG. 11 and FIG. 13A, in this example, plugs contacting the first drain select line DSL1 are selected plugs Sel_PL coupled to the first bit line BL1 and the third bit line BL3 and plugs contacting the second drain select line DSL2 are selected plugs Sel_PL coupled to the second bit line BL2 and the fourth bit line BL4. Each selected plug Sel_PL is a plug coupled to a bit line to which a program-enable voltage is applied. The bit line to which the program-enable voltage is applied is a bit line coupled to a page buffer to which data ‘0’ is input.

A ground voltage GND is applied to the source line SL, and all of the source select transistors SST are turned off. As a result, the selected plugs Sel_PL are not coupled to the source line SL. A pass voltage Vpass is applied to unselected word lines Unsel_WL and a selected word line Sel_WL. The pass voltage Vpass is a positive voltage capable of turning on the memory cells. The turn-on voltage Von is applied to the drain select lines DSL1 and DSL2 and may be simultaneously applied to the drain select lines DSL1 and DSL2. Due to the turn-on voltage Von applied to the drain select lines DSL1 and DSL2, the drain select transistors DST coupled to the drain select lines DSL1 and DSL2 are turned on.

A precharge voltage Vpre is applied to the bit lines BL1 to BL4. The precharge voltage Vpre may be a positive voltage higher than 0 V.

Because all of the drain select transistors DST coupled to the drain select lines DSL1 and DSL2 are turned on, the precharge voltage Vpre applied to the bit lines BL1 to BL4 is applied to the channels 1CH to 4CH of the selected plugs Sel_PL. Therefore, the channels 1CH to 4CH may be simultaneously precharged to the precharge voltage Vpre.

Referring to FIG. 11 and FIG. 13B, after the channels 1CH to 4CH are precharged, as described with reference to FIG. 13A, the program-enable voltage Val is applied to the bit lines BL1 to BL4 depending on data of the page buffers coupled to the bit lines BL1 to BL4. In this example, the data input to the page buffers coupled to the bit lines BL1 to BL4 are ‘0’. When data ‘0’ is data that increases the threshold voltage of a memory cell and data ‘1’ is set to data that maintains the threshold voltage of a memory cell in a previous state, the page buffer to which data ‘0’ is input outputs the program-enable voltage Val through the corresponding bit line. As described with reference to FIG. 13A, the plugs to which the program-enable voltage Val is applied are the selected plugs Sel_PL.

Because the drain select transistors DST coupled to the drain select lines DSL1 and DSL2 are turned on, the program-enable voltage Val applied to the bit lines BL1 to BL4 is transferred to the channels 1CH to 4CH of the selected plugs Sel_PL. Therefore, the voltages of the channels 1CH to 4CH decrease to the program-enable voltage Val. Because the source select transistors SST are turned on, the voltages of the channels 1CH to 4CH are at voltage levels lower than the voltage level of the program-enable voltage Val.

In order to increase the threshold voltages of the selected memory cells among memory cells coupled to the selected word line Sel_WL, the pass voltage Vpass is applied to the unselected word lines Unsel_WL, and a program voltage Vpgm is applied to the selected word line Sel_WL. Among the memory cells included in the selected plugs Sel_PL, memory cells coupled to the selected word line Sel_WL are selected memory cells.

The turn-on voltage is applied to the source select lines, thus the source select transistors SST are turned on. Therefore, the channels 1CH to 4CH of the selected plugs Sel_PL are electrically connected to the source line SL. As a result, the voltages of the channels 1CH to 4CH are lower than or equal to the program-enable voltage Val.

The selected memory cells of the selected plugs Sel_PL are programmed due to the voltage difference between the program voltage Vpgm applied to the selected word line Sel_WL and the program-enable voltage Val applied to each of the channels 1CH to 4CH. For example, when a voltage difference enabling programming is a reference voltage difference, the voltage difference between the gate and the channel of each selected memory cell is equal to or higher than the reference voltage difference.

Because the selected memory cells of the plugs coupled to different drain select lines DSL1 and DSL2, are simultaneously programmed, program disturb in the Y direction, the X direction, or the XY direction (such as a diagonal direction between the X direction and the Y direction) may be mitigated.

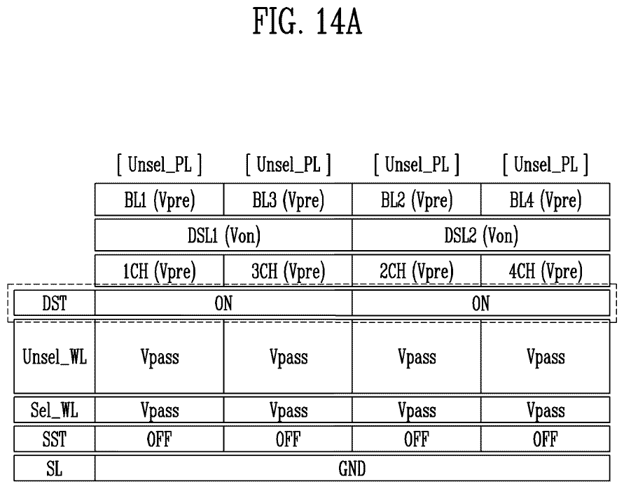

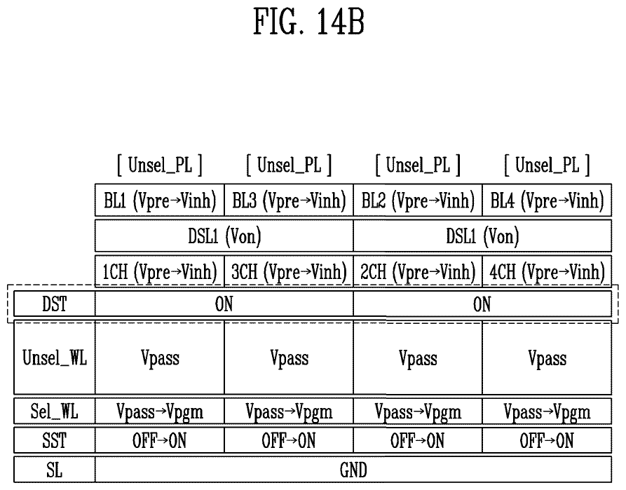

FIG. 14A and FIG. 14B are tables including voltages and transistor states during a program operation according to a second embodiment of the present disclosure when all plugs are unselected plugs.

Referring to FIG. 11 and FIG. 14A, in this example, plugs contacting the first drain select line DSL1 are unselected plugs Unsel_PL coupled to the first bit line BL1 and the third bit line BL3 and plugs contacting the second drain select line DSL2 are unselected plugs Unsel_PL coupled to the second bit line BL2 and the fourth bit line BL4. Each unselected plug Unsel_PL is a plug coupled to a bit line to which a program-inhibit voltage is applied. The bit line to which the program-inhibit voltage is applied is a bit line coupled to a page buffer to which data ‘1’ is input.

A ground voltage GND is applied to a source line SL, and all of the source select transistors SST are turned off. As a result, the unselected plugs Unsel_PL are not coupled to the source line SL. A pass voltage Vpass is applied to unselected word lines Unsel_WL and a selected word line Sel_WL. The pass voltage Vpass is a positive voltage capable of turning on the memory cells. The turn-on voltage Von is applied to the drain select lines DSL1 and DSL2 and may be simultaneously applied to the drain select lines DSL1 and DSL2. Due to the turn-on voltage Von applied to the drain select lines DSL1 and DSL2, the drain select transistors DST coupled to the drain select lines DSL1 and DSL2 are turned on.

A precharge voltage Vpre is applied to the bit lines BL1 to BL4. The precharge voltage Vpre may be a positive voltage higher than 0 V.

Because all of the drain select transistors DST coupled to the drain select lines DSL1 and DSL2 are turned on, the precharge voltage Vpre applied to the bit lines BL1 to BL4 is applied to the channels 1CH to 4CH of the selected plugs Sel_PL. Therefore, the channels 1CH to 4CH may be simultaneously precharged to the precharge voltage Vpre.

Referring to FIG. 11 and FIG. 14B, after the channels 1CH to 4CH are precharged, as described with reference to FIG. 14A, the program-inhibit voltage Vinh is applied to the bit lines BL1 to BL4 depending on data of the page buffers coupled to the bit lines BL1 to BL4. In this example, data input to the page buffers coupled to the bit lines BL1 to BL4 are ‘1’. When data ‘0’ is data that increases the threshold voltage of a memory cell and data ‘1’ is data that maintains the threshold voltage of a memory cell in a previous state, the page buffer to which data ‘1’ is input outputs the program-inhibit voltage Vinh through the corresponding bit line. Therefore, as described with reference to FIG. 14A, the plugs to which the program-inhibit voltage Vinh is applied are the unselected plugs Unsel_PL.

Because the drain select transistors DST coupled to the drain select lines DSL1 and DSL2 are turned on, the program-inhibit voltage Vinh applied to the bit lines BL1 to BL4 is transferred to the channels 1CH to 4CH of the unselected plugs Unsel_PL. Therefore, the voltages of the channels 1CH to 4CH increase to the program-inhibit voltage Vinh. Because the source select transistors SST are turned on, the voltages of the channels 1CH to 4CH are at voltage levels lower than the voltage level of the program-inhibit voltage Vinh.

In order to increase the threshold voltage of a selected memory cell among memory cells coupled to the selected word line Sel_WL, the pass voltage Vpass is applied to the unselected word lines Unsel_WL, and a program voltage Vpgm is applied to the selected word line Sel_WL. Among the memory cells included in the unselected plugs Unsel_PL, a memory cell coupled to the selected word line Sel_WL is an unselected memory cell.

The turn-on voltage is applied to the source select lines, thus the source select transistors SST are turned on. Therefore, the channels 1CH to 4CH are electrically connected to the source line SL. As a result, the voltages of the channels 1CH to 4CH are lower than or equal to the program-inhibit voltage Vinh.

The unselected memory cells of the unselected plugs Unsel_PL are program-inhibited due to the voltage difference between the program voltage Vpgm applied to the selected word line Sel_WL and the program-inhibit voltage Vinh applied to each of the channels 1CH to 4CH. For example, the voltage difference between the gate and the channel of each unselected memory cell is lower than the reference voltage difference. For example, when a voltage difference enabling programming is a reference voltage difference, the voltage difference between the gate and the channel of each unselected memory cell is lower than the reference voltage difference.

Even when the voltages of the channels 1CH to 4CH are lower than the program-inhibit voltage Vinh, the level of the program-inhibit voltage Vinh is sufficiently high to prevent the threshold voltages of unselected memory cells from increasing, and the program-inhibit voltage Vinh continues to be supplied to the channels 1CH to 4CH through the bit lines BL1 to BL4. Accordingly, the memory cells coupled to the selected word line Sel_WL among the memory cells included in the unselected plugs Unsel_PL are program-inhibited while the program operation is performed on the selected memory cells coupled to the selected word line Sel_WL.

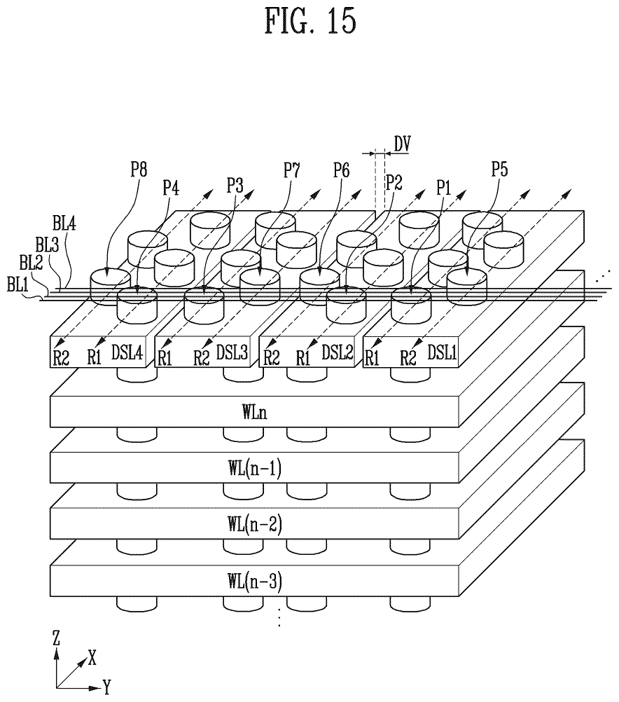

FIG. 15 is a perspective view illustrating the structure of a memory block according to a third embodiment of the present disclosure.

Referring to FIG. 15, the memory block according to the third embodiment includes four drain select lines, for example, first drain select line DSL1, second drain select line DSL2, third drain select line DSL3, and fourth drain select line DSL4, also referred to as drain select lines DSL1 to DSL 4. Each of the drain select lines DSL1 to DSL4 contacts plugs arranged along a first row R1 and a second row R2. For example, the first plugs P1 arranged along the first row R1 and the fifth plugs P5 arranged along the second row R2 contact the first drain select line DSL1. The second plugs P2 arranged along the first row R1 and the sixth plugs P6 arranged along the second row R2 contact the second drain select line DSL2. The third plugs P3 arranged along the first row R1 and the seventh plugs P7 arranged along the second row R2 contact the third drain select line DSL3. The fourth plugs P4 arranged along the first row R1 and the eighth plugs P8 arranged along the second row R2 contact the fourth drain select line DSL4.

The first plugs P1 and the fifth plugs P5 penetrate the first drain select line DSL1 and the word lines WL(n−3) to WLn, the second plugs P2 and the sixth plugs P6 penetrate the second drain select line DSL2 and the word lines WL(n−3) to WLn, the third plugs P3 and the seventh plugs P7 penetrate the third drain select line DSL3 and the word lines WL(n−3) to WLn, and the fourth plugs P4 and the eighth plugs P8 penetrate the fourth drain select line DSL4 and the word lines WL(n−3) to WLn.

In the remaining region of the memory block, not illustrated in FIG. 15, the plugs P1 to P8 penetrate the remaining word lines W1 to WL(n−4) and source select lines.

The first row R1 of first plugs P1 and the first row R1 of second plugs P2 may be symmetrical to each other with respect to a division region DV between the first drain select line DSL1 and the second drain select line DSL2, the first row R1 of second plugs P2 and the first row R1 of third plugs P3 may be symmetrical to each other with respect to a division region DV between the second drain select line DSL2 and the third drain select line DSL3, and the first row R1 of third plugs P3 and the first row R1 of fourth plugs P4 may be symmetrical to each other with respect to a division region DV between the third drain select line DSL3 and the fourth drain select line DSL4. The second row R2 of fifth plugs P5 and the second row R2 of sixth plugs P6 may be symmetrical to each other with respect to the division region DV between the first drain select line DSL1 and the second drain select line DSL2, the second row R2 of sixth plugs P6 and the second row R2 of seventh plugs P7 may be symmetrical to each other with respect to the division region DV between the second drain select line DSL2 and the third drain select line DSL3, and the second row R2 of seventh plugs P7 and the second row R2 of eighth plugs P8 may be symmetrical to each other with respect to the division region DV between the third drain select line DSL3 and the fourth drain select line DSL4.

The plugs P1 to P8 may have the same structure. The planar structure or cross section of each of the plugs P1 to P8 is similar to the structure described with reference to FIG. 5.

A plurality of bit lines BL1 to BL4 are arranged on the plugs P1 to P8. FIG. 15 illustrates a portion of the memory block. The quantity of bit lines is not limited to the quantity of bit lines illustrated in FIG. 15. Only four bit lines, for example, bit lines BL1 to BL4, disposed on the plugs P1 to P4, are illustrated for convenience of description. The bit lines BL1 to BL4 individually extend along the Y direction, and are spaced apart from each other along the X direction. Each of the bit lines BL1 to BL4 contacts one plug. For example, the first bit line BL1 contacts one of the first plugs P1, the second bit line BL2 contacts one of the second plugs P2, the third bit line BL3 contacts one of the third plugs P3, and the fourth bit line BL4 contacts one of the fourth plugs P4.

In the described embodiments, although the quantity of separated drain select lines is illustrated as 2 or 4, the embodiments may be applied to a memory device including three or more separated drain select lines.

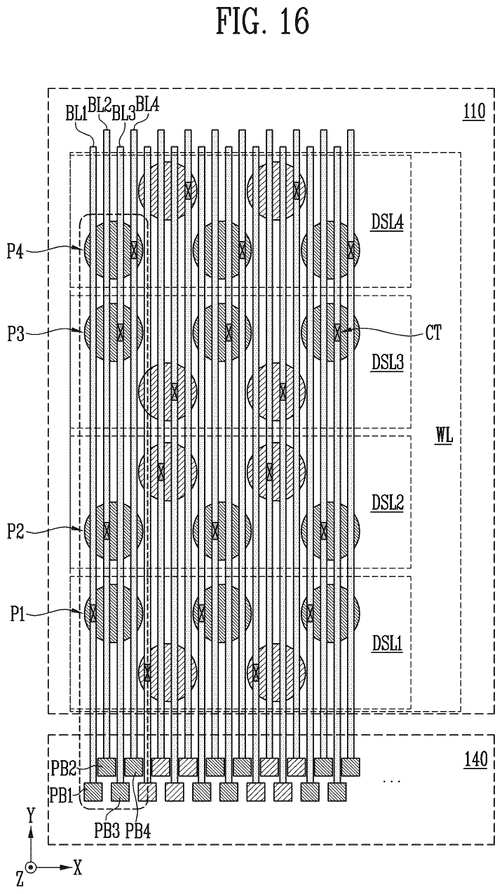

FIG. 16 is a layout view illustrating a connection relationship between a memory block and page buffers according to a third embodiment of the present disclosure.

Referring to FIG. 15 and FIG. 16, the bit lines BL1 to BL4 are coupled to page buffers PB1 to PB4, respectively.

The plugs P1 to P4 contacting the bit lines BL1 to BL4 are described.

The first plug P1 contacts the first bit line BL1 through a contact CT. The second plug P2 contacts the second bit line BL2 through a contact CT. The third plug P3 contacts the third bit line BL3 through a contact CT. The fourth plug P4 contacts the fourth bit line BL4 through a contact CT.

When a turn-on voltage is applied to the first drain select line DSL1, the first plug P1 is electrically connected to the first page buffer PB1 through a contact CT and the first bit line BL1. When a turn-on voltage is applied to the second drain select line DSL2, the second plug P2 is electrically connected to the second page buffer PB2 through a contact CT and the second bit line BL2. When a turn-on voltage is applied to the third drain select line DSL3, the third plug P3 is electrically connected to the third page buffer PB3 through the contact CT and the third bit line BL3. When a turn-on voltage is applied to the four drain select line DSL4, the fourth plug P3 is electrically connected to the fourth page buffer PB4 through a contact CT and the fourth bit line BL4.

When the turn-on voltage is simultaneously applied to the drain select lines DSL1 to DSL4, the P1 to P4 are simultaneously electrically connected to the page buffers PB1 to PB4, respectively.

During a program operation, even though the plugs P1 to P4 are simultaneously selected, the plugs P1 to P4 are electrically connected to different bit lines BL1 to BL4, thus the program operation may be simultaneously performed on the plugs P1 to P4.

Because the plugs contacting the drain select lines DSL1 to DSL4 may be selected plugs or unselected plugs depending on the data input to the page buffers, program operations for various examples are described.

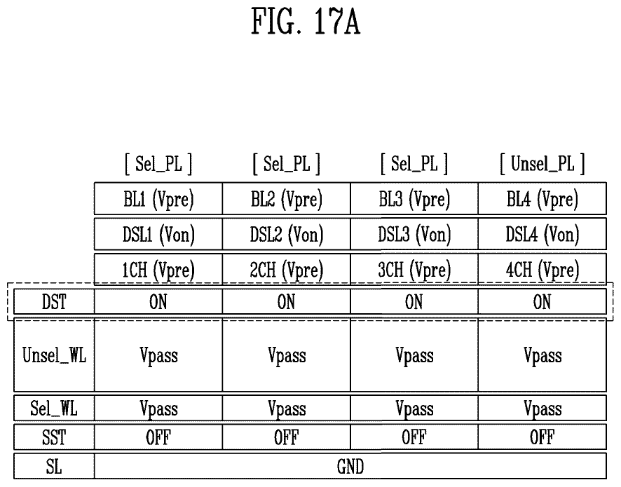

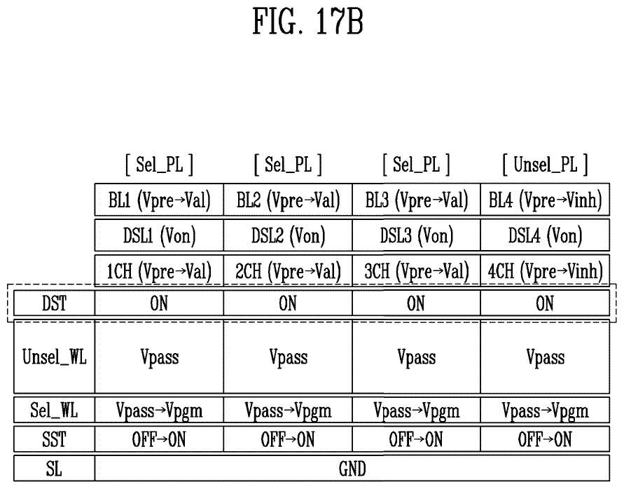

FIG. 17A and FIG. 17B are tables including voltages and transistor states during a program operation according to a third embodiment of the present disclosure when at least one of plugs is unselected.

Referring to FIG. 16 and FIG. 17A, in this example, plugs contacting the drain select lines DSL1 to DSL3 are selected plugs Sel_PL coupled to the bit lines BL1 to BL3, respectively, and a plug contacting the fourth drain select line DSL4 is an unselected plug Unsel_PL coupled to the fourth bit line BL4. Each selected plug Sel_PL is a plug coupled to a bit line to which a program-enable voltage is applied. The bit line to which the program-enable voltage is applied is a bit line coupled to a page buffer to which data ‘0’ is input. The unselected plug Unsel_PL is a plug coupled to a bit line to which a program-inhibit voltage is applied. The bit line to which the program-inhibit voltage is applied is a bit line coupled to a page buffer to which data ‘1’ is input.

A ground voltage GND is applied to a source line SL, and all of the source select transistors SST are turned off. As a result, the selected plugs Sel_PL and the unselected plug Unsel_PL are not coupled to the source line SL. A pass voltage Vpass is applied to unselected word lines Unsel_WL and a selected word line Sel_WL. The pass voltage Vpass is a positive voltage capable of turning on the memory cells. The turn-on voltage Von is applied to the drain select lines DSL1 to DSL4 and may be simultaneously applied to the drain select lines DSL1 to DSL4. Due to the turn-on voltage Von applied to the drain select lines DSL1 to DSL4, the drain select transistors DST coupled to the drain select lines DSL1 to DSL4 are turned on.

A precharge voltage Vpre is applied to the bit lines BL1 to BL4. The precharge voltage Vpre may be a positive voltage higher than 0 V.

Because all of the drain select transistors DST coupled to the drain select lines DSL1 to DSL4 are turned on, the precharge voltage Vpre applied to the bit lines BL1 to BL4 is applied to the channels 1CH to 3CH of the selected plugs Sel_PL and the fourth channel 4CH of the unselected plug Unsel_PL. Therefore, the channels 1CH to 4CH may be simultaneously precharged to the precharge voltage Vpre.

Referring to FIG. 16 and FIG. 17B, after the channels 1CH to 4CH are precharged, as described with reference to FIG. 17A, the program-enable voltage Val is applied to the bit lines BL1 to BL3, and the program-inhibit voltage Vinh is applied to the fourth bit line BL4, depending on data of the page buffers coupled to the bit lines BL1 to BL4. In this example, data input to the page buffers coupled to the bit lines BL1 to BL3 are ‘0’ and data input to the page buffer coupled to the fourth bit line BL4 is ‘1’. When data ‘0’ is data that increases the threshold voltage of a memory cell and data ‘1’ is data that maintains the threshold voltage of the memory cell in a previous state, the page buffer to which data ‘0’ is input outputs the program-enable voltage Val through the corresponding bit line, and the page buffer to which data ‘1’ is input outputs the program-inhibit voltage Vinh through the corresponding bit line. Therefore, as described with reference to FIG. 17A, the plugs to which the program-enable voltage Val is applied are selected plugs Sel_PL, and the plug to which the program-inhibit voltage Vinh is applied is an unselected plug Unsel_PL. The program-inhibit voltage Vinh may be a positive voltage higher than the program-enable voltage Val.

Because the drain select transistors DST coupled to the drain select lines DSL1 to DSL4 are turned on, the program-enable voltage Val applied to the bit lines BL1 to BL3 is transferred to the channels 1CH to 3CH of the selected plugs Sel_PL, and the program-inhibit voltage Vinh applied to the fourth bit line BL4 is transferred to the fourth channel 4CH of the unselected plug Unsel_PL. Therefore, the voltages of the channels 1CH to 3CH decrease to the program-enable voltage Val, and the voltage of the fourth channel 4CH increases to the program-inhibit voltage Vinh. Because the source select transistors SST are turned on, the voltages of the channels 1CH to 3CH are at a voltage level lower than the voltage level of the program-enable voltage Val, and the voltage of the fourth channel 4CH is at a voltage level lower than the voltage level of the program-inhibit voltage Vinh.

In order to increase the threshold voltages of the selected memory cells among memory cells coupled to the selected word line Sel_WL, the pass voltage Vpass is applied to the unselected word lines Unsel_WL, and a program voltage Vpgm is applied to the selected word line Sel_WL. Memory cells coupled to the selected word line Sel_WL among the memory cells included in the selected plugs Sel_PL are the selected memory cells, and a memory cell coupled to the selected word line Sel_WL among the memory cells included in the unselected plug Unsel_PL is an unselected memory cell.

The turn-on voltage is applied to the source select lines, thus the source select transistors SST are turned on. Therefore, the channels 1CH to 3CH of the selected plugs Sel_PL and the fourth channel 4CH of the unselected plug Unsel_PL are electrically connected to the source line SL. As a result, the voltages of the channels 1CH to 3CH are lower than or equal to the program-enable voltage Val, and the voltage of the fourth channel 4CH is lower than or equal to the program-inhibit voltage Vinh.

The selected memory cells of the selected plugs Sel_PL are programmed due to the voltage difference between the program voltage Vpgm applied to the selected word line Sel_WL and the program-enable voltage Val applied to each of the channels 1CH to 3CH. For example, when a voltage difference enabling programming is a reference voltage difference, the voltage difference between the gate and the channel of each selected memory cell is equal to or higher than the reference voltage difference.

The unselected memory cell of the unselected plug Unsel_PL is program-inhibited due to the voltage difference between the program voltage Vpgm applied to the selected word line Sel_WL and the program-inhibit voltage Vinh applied to the fourth channel 4CH. For example, the voltage difference between the gate and the channel of the unselected memory cell is lower than the reference voltage difference.

Even when the voltage of the fourth channel 4CH is lower than the program-inhibit voltage Vinh, the level of the program-inhibit voltage Vinh is sufficiently high to prevent the threshold voltages of unselected memory cells from increasing, and the program-inhibit voltage Vinh continues to be supplied to the fourth channel 4CH through the fourth bit line BL4. Therefore, the memory cell coupled to the selected word line Sel_WL among the memory cells included in the unselected plug Unsel_PL is program-inhibited.

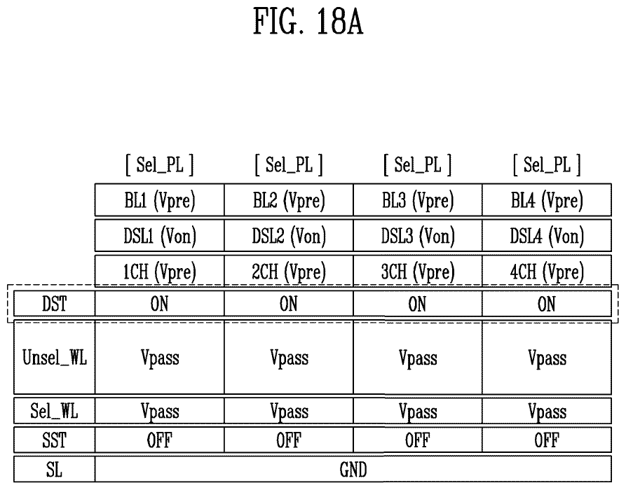

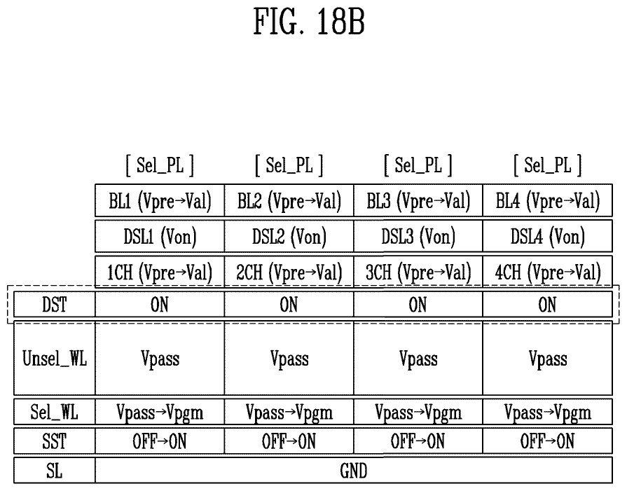

FIG. 18A and FIG. 18B are tables including voltages and transistor states during a program operation according to a third embodiment of the present disclosure when all plugs are selected plugs.

Referring to FIG. 16 and FIG. 18A, in this example, plugs contacting the drain select lines DSL1 to DSL4 are selected plugs Sel_PL coupled to the bit lines BL1 to BL4, respectively. Each selected plug Sel_PL is a plug coupled to a bit line to which a program-enable voltage is applied. The bit line to which the program-enable voltage is applied is a bit line coupled to a page buffer to which data ‘0’ is input.

A ground voltage GND is applied to a source line SL, and all of the source select transistors SST are turned off. As a result, the selected plugs Sel_PL are not coupled to the source line SL. A pass voltage Vpass is applied to unselected word lines Unsel_WL and a selected word line Sel_WL. The pass voltage Vpass is a positive voltage capable of turning on the memory cells. The turn-on voltage Von is applied to the drain select lines DSL1 to DSL4 and may be simultaneously applied to the drain select lines DSL1 to DSL4. Due to the turn-on voltage Von applied to the drain select lines DSL1 to DSL4, all of the drain select transistors DST coupled to the drain select lines DSL1 to DSL4 are turned on.

A precharge voltage Vpre is applied to the bit lines BL1 to BL4. The precharge voltage Vpre may be a positive voltage higher than 0 V.

Because all of the drain select transistors DST coupled to the drain select lines DSL1 to DSL4 are turned on, the precharge voltage Vpre applied to the bit lines BL1 to BL4 is applied to the channels 1CH to 4CH of the selected plugs Sel_PL. Therefore, the channels 1CH to 4CH may be simultaneously precharged to the precharge voltage Vpre.

Referring to FIG. 16 and FIG. 18B, after the channels 1CH to 4CH are precharged, as described with reference to FIG. 18A, the program-enable voltage Val is applied to the bit lines BL1 to BL4 depending on data of the page buffers coupled to the bit lines BL1 to BL4. In this example, the data input to the page buffers coupled to the bit lines BL1 to BL4 are ‘0’. When data ‘0’ is data that increases the threshold voltage of a memory cell and data ‘1’ is data that maintains the threshold voltage of a memory cell in a previous state, the page buffer to which data ‘0’ is input outputs the program-enable voltage Val through the corresponding bit line. As described with reference to FIG. 18A, plugs to which the program-enable voltage Val is applied are the selected plugs Sel_PL.

Because all of the drain select transistors DST coupled to the drain select lines DSL1 to DSL4 are turned on, the program-enable voltage Val applied to the bit lines BL1 to BL4 is applied to the channels 1CH to 4CH of the selected plugs Sel_PL. Therefore, the voltages of the channels 1CH to 4CH decrease to the program-enable voltage Val. Because the source select transistors SST are turned on, the voltages of the channels 1CH to 4CH are at voltage levels lower than the voltage level of the program-enable voltage Val.

In order to increase the threshold voltages of the selected memory cells among memory cells coupled to the selected word line Sel_WL, the pass voltage Vpass is applied to the unselected word lines Unsel_WL, and a program voltage Vpgm is applied to the selected word line Sel_WL. Among the memory cells included in the selected plugs Sel_PL, memory cells coupled to the selected word line Sel_WL are selected memory cells.

The turn-on voltage is applied to the source select lines, thus the source select transistors SST are turned on. Therefore, the channels 1CH to 4CH of the selected plugs Sel_PL are electrically connected to the source line SL. As a result, the voltages of the channels 1CH to 4CH are lower than or equal to the program-enable voltage Val.

The selected memory cells of the selected plugs Sel_PL are programmed due to the voltage difference between the program voltage Vpgm applied to the selected word line Sel_WL and the program-enable voltage Val applied to each of the channels 1CH to 4CH. For example, when a voltage difference enabling programming is a reference voltage difference, the voltage difference between the gate and the channel of each selected memory cell is equal to or higher than the reference voltage difference.

Because the selected memory cells of the plugs coupled to different drain select lines DSL1 to DSL4, are simultaneously programmed, program disturb in a Y direction, an X direction, or an XY direction (such as a diagonal direction between the X direction and the Y direction) may be mitigated.

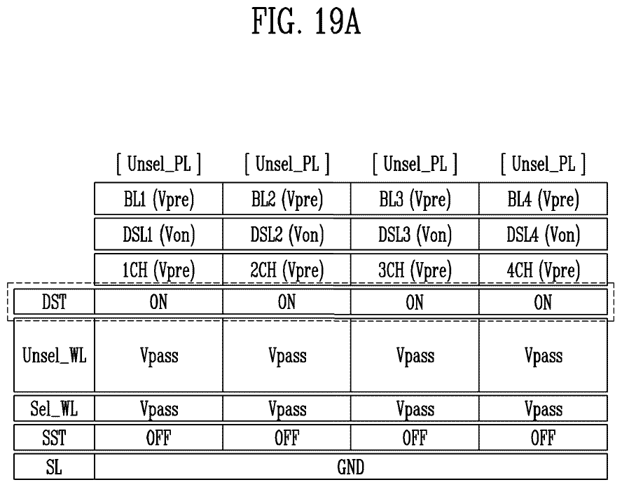

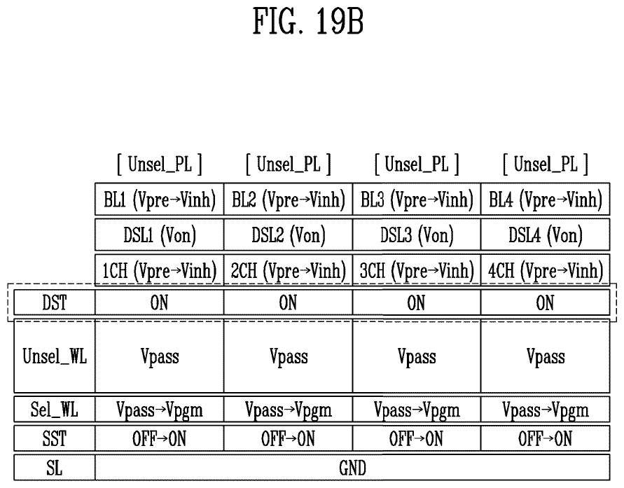

FIG. 19A and FIG. 19B are tables including voltages and transistor states during a program operation according to a third embodiment of the present disclosure when all plugs are unselected plugs.

Referring to FIG. 16 and FIG. 19A, in this example, plugs contacting the drain select lines DSL1 to DSL4 are unselected plugs Unsel_PL coupled to the bit lines BL1 to BL4, respectively. Each unselected plug Unsel_PL is a plug coupled to a bit line to which a program-inhibit voltage is applied. The bit line to which the program-inhibit voltage is applied is a bit line coupled to a page buffer to which data ‘1’ is input.

A ground voltage GND is applied to a source line SL, and all of the source select transistors SST are turned off. As a result, the unselected plugs Unsel_PL are not coupled to the source line SL. A pass voltage Vpass is applied to unselected word lines Unsel_WL and a selected word line Sel_WL. The pass voltage Vpass is a positive voltage capable of turning on the memory cells. The turn-on voltage Von is applied to the drain select lines DSL1 to DSL4 and may be simultaneously applied to the drain select lines DSL1 to DSL4. Due to the turn-on voltage Von applied to the drain select lines DSL1 to DSL4, the drain select transistors DST coupled to the select lines DSL1 to DSL4 are turned on.

A precharge voltage Vpre is applied to the bit lines BL1 to BL4. The precharge voltage Vpre may be a positive voltage higher than 0 V.

Because all of the drain select transistors DST coupled to the drain select lines DSL1 to DSL4 are turned on, the precharge voltage Vpre applied to the bit lines BL1 to BL4 is applied to the channels 1CH to 4CH of the selected plugs Sel_PL. Therefore, the channels 1CH to 4CH may be simultaneously precharged to the precharge voltage Vpre.

Referring to FIG. 16 and FIG. 19B, after the channels 1CH to 4CH are precharged, as described with reference to FIG. 19A, the program-inhibit voltage Vinh is applied to the bit lines BL1 to BL4 depending on data of the page buffers coupled to the bit lines BL1 to BL4. In this example, data input to the page buffers coupled to the bit lines BL1 to BL4 are ‘1’. When data ‘0’ is data that increases the threshold voltage of a memory cell and data ‘1’ is data that maintains the threshold voltage of a memory cell in a previous state, the page buffer to which data ‘1’ is input outputs the program-inhibit voltage Vinh through the corresponding bit line. Therefore, as described with reference to FIG. 19A, the plugs to which the program-inhibit voltage Vinh is applied are the unselected plugs Unsel_PL.

Because all of the drain select transistors DST coupled to the drain select lines DSL1 to DSL4 are turned on, the program-inhibit voltage Vinh applied to the bit lines BL1 to BL4 is transferred to the channels 1CH to 4CH of the unselected plugs Unsel_PL. Therefore, the voltages of the channels 1CH to 4CH increase to the program-inhibit voltage Vinh. Because the source select transistors SST are turned on, the voltages of the channels 1CH to 4CH are at voltage levels lower than the voltage level of the program-inhibit voltage Vinh.

In order to increase the threshold voltage of a selected memory cell among memory cells coupled to the selected word line Sel_WL, the pass voltage Vpass is applied to the unselected word lines Unsel_WL, and a program voltage Vpgm is applied to the selected word line Sel_WL. Among the memory cells included in the unselected plugs Unsel_PL, a memory cell coupled to the selected word line Sel_WL is an unselected memory cell.

The turn-on voltage is applied to the source select lines, thus the source select transistors SST are turned on. Therefore, the channels 1CH to 4CH are electrically connected to the source line SL. As a result, the voltages of the channels 1CH to 4CH are lower than or equal to the program-inhibit voltage Vinh.

The unselected memory cells of the unselected plugs Unsel_PL are program-inhibited due to the voltage difference between the program voltage Vpgm applied to the selected word line Sel_WL and the program-inhibit voltage Vinh applied to each of the channels 1CH to 4CH. For example, the voltage difference between the gate and the channel of each unselected memory cell is lower than the reference voltage difference. For example, when a voltage difference enabling programming is a reference voltage difference, the voltage difference between the gate and the channel of each unselected memory cell is lower than the reference voltage difference.

Even when the voltages of the channels 1CH to 4CH is lower than the program-inhibit voltage Vinh, the level of the program-inhibit voltage Vinh is sufficiently high to prevent the threshold voltages of unselected memory cells from increasing, and the program-inhibit voltage Vinh continues to be supplied to the channels 1CH to 4CH through the lines BL1 to BL4. Accordingly, the memory cells coupled to the selected word line Sel_WL among the memory cells included in the unselected plugs Unsel_PL are program-inhibited while the program operation is performed on the selected memory cells coupled to the selected word line Sel_WL.

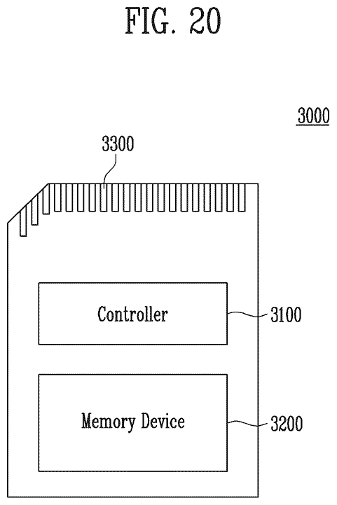

FIG. 20 is a diagram illustrating an embodiment of a memory card system including a memory device according to the present disclosure.

Referring to FIG. 20, a memory card system 3000 includes a controller 3100, a memory device 3200, and a connector 3300.

The controller 3100 is coupled to the memory device 3200. The controller 3100 accesses the memory device 3200. For example, the controller 3100 is configured to control a program operation, a read operation, an erase operation of the memory device 3200, and background operations of the memory device 3200. The controller 3100 is configured to provide an interface between the memory device 3200 and a host. The controller 3100 runs firmware that controls the memory device 3200. In an embodiment, the controller 3100 may include components, such as a RAM, a processor, a host interface, a memory interface, and an error correction circuit.

The controller 3100 communicates with an external device through the connector 3300. The controller 3100 communicates with an external device, for example, a host, based on a specific communication standard or protocol. In an embodiment, the controller 3100 may be configured to communicate with the external device through at least one of various communication standards such as universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). In an embodiment, the connector 3300 may be configured according to at least one of the above communication standards.

The memory device 3200 includes a plurality of memory cells, configured, for example, in the same manner as the memory device 100 illustrated in FIG. 1. The memory device 3200 is configured to perform the method of program operation as described with respect to FIG. 1 through FIG. 19. For example, the method suppresses an increase in the threshold voltages of unselected memory cells.

The controller 3100 and the memory device 3200 are integrated into a single semiconductor device to form a memory card. For example, the controller 3100 and the memory device 3200 may be integrated into a single semiconductor device and may form a memory card such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, SDHC), a universal flash storage (UFS), or the like.

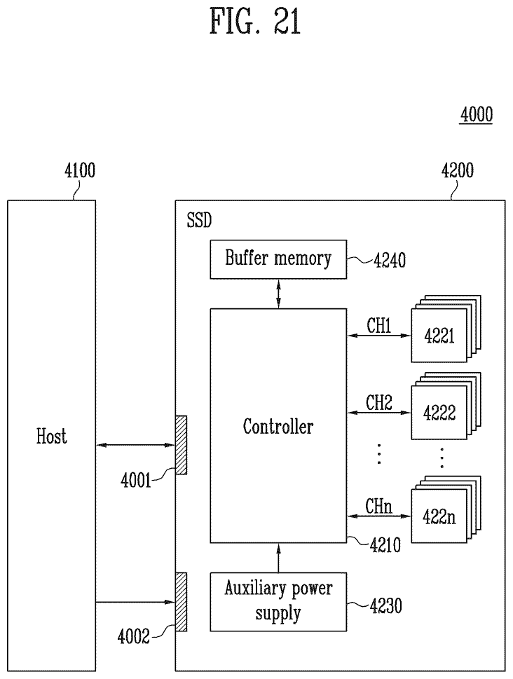

FIG. 21 is a diagram illustrating an embodiment of a solid state drive (SSD) system including a memory device according to the present disclosure.

Referring to FIG. 21, an SSD system 4000 includes a host 4100 and an SSD 4200. The SSD 4200 exchanges signals with the host 4100 through a signal connector 4001 and receives power through a power connector 4002. The SSD 4200 includes a controller 4210, a plurality of memory devices 4221 to 422n, an auxiliary power supply 4230, and a buffer memory 4240.

The controller 4210 controls the plurality of memory devices 4221 to 422n in response to signals received from the host 4100. In an embodiment, the signal may include signals based on the interfaces of the host 4100 and the SSD 4200. For example, the signal may be configured or constructed according to at least one of a plurality of interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n includes a plurality of memory cells configured to store data. Each of the plurality of memory devices 4221 to 422n is configured, for example, in the same manner as the memory device 100 illustrated in FIG. 1. The plurality of memory devices 4221 to 422n communicates with the controller 4210 through channels CH1 to CHn. Each of the plurality of memory devices 4221 to 422n is configured to perform the method of program operation as described with respect to FIG. 1 through FIG. 19. For example, the method suppresses an increase in the threshold voltages of unselected memory cells.

The auxiliary power supply 4230 is coupled to the host 4100 through the power connector 4002. The auxiliary power supply 4230 is supplied with a supply voltage from the host 4100 and may be charged. The auxiliary power supply 4230 may provide the supply voltage for the SSD 4200 when the supply of power from the host 4100 is not smooth or consistent. In an embodiment, the auxiliary power supply 4230 may be located inside the SSD 4200 or located outside the SSD 4200. For example, the auxiliary power supply 4230 may be located on a main board and may also provide auxiliary power to the SSD 4200.

The buffer memory 4240 functions as a buffer memory for the SSD 4200. For example, the buffer memory 4240 temporarily stores data received from the host 4100 or data received from the plurality of memory devices 4221 to 422n or temporarily stores metadata, for example, mapping tables, of the memory devices 4221 to 422n. The buffer memory 4240 may include one or more volatile memories, such as a DRAM, SDRAM, DDR SDRAM, and LPDDR SDRAM, or nonvolatile memories, such as an FRAM, ReRAM, STT-MRAM, and PRAM.

The present disclosure describes embodiments that may suppress an increase in the threshold voltages of unselected memory cells, thus improving the reliability of a memory device.

Concepts in conjunction with various embodiments are described above. Those skilled in the art will understand that various modifications, additions, and substitutions are possible, without departing from the scope and spirit of the present disclosure. Accordingly, the embodiments disclosed in the present specification should be considered not from a restrictive standpoint but rather from an illustrative standpoint. Therefore, the scope of the present disclosure should not be limited to the foregoing embodiments. All changes within the meaning and range of equivalency of the claims are to be included within their scope.

What is claimed is:

1. A method of operating a memory device, the method comprising:
precharging a first channel of a first plug corresponding to a first select line and a second channel of a second plug corresponding to a second select line;
applying one of a program-enable voltage and a program-inhibit voltage to the first channel;
applying one of the program-enable voltage and the program-inhibit voltage to the second channel; and
programming memory cells selected from among memory cells included in the first plug and the second plug.

2. The method according to claim 1, wherein the program-inhibit voltage is a higher than the program-enable voltage.

3. The method according to claim 1, wherein precharging the first channel and the second channel comprises:
applying a precharge voltage to a first bit line coupled to the first plug;
applying the precharge voltage to a second bit line coupled to the second plug;
applying a pass voltage to word lines coupled in common to the first plug and the second plug;
turning on a first select transistor between the first channel and the first bit line; and
turning on a second select transistor between the second channel and the second bit line.

4. The method according to claim 3, wherein the precharge voltage is a voltage higher than 0 V.

5. The method according to claim 3, wherein:
turning on the first select transistor comprises applying a turn-on voltage to the first select line coupled to a gate of the first select transistor, and
turning on the second select transistor comprises applying the turn-on voltage to the second select line coupled to a gate of the second select transistor.

6. The method according to claim 1, wherein applying one of the program-enable voltage and the program-inhibit voltage to the first channel comprises:
inputting data to a first page buffer; and
outputting, by the first page buffer, one of the program-enable voltage and the program-inhibit voltage to a first bit line coupled to the first plug depending on the data.

7. The method according to claim 1, wherein applying one of the program-enable voltage and the program-inhibit voltage to the second channel comprises:
inputting data to a second page buffer; and
outputting, by the second page buffer, one of the program-enable voltage and the program-inhibit voltage to a second bit line coupled to the second plug depending on the data.

8. The method according to claim 1, where programming the selected memory cells comprises:
applying a pass voltage to unselected word lines among word lines coupled to the first plug and the second plug; and
applying a program voltage to a selected word line among the word lines.

9. The method according to claim 1, further comprising when the selected memory cells are included in the first plug and the second plug, applying the program-enable voltage to the first channel and the second channel.

10. The method according to claim 1, further comprising:
when the selected memory cells are included in the first plug and are not included in the second plug,
applying the program-enable voltage to the first channel; and
applying the program-inhibit voltage to the second channel.

11. The method according to claim 1, further comprising when the selected memory cells are not included in the first plug and the second plug, applying the program-inhibit voltage to the first channel and the second channel.

12. A method of operating a memory device, the method comprising:
precharging a first channel of a first plug and a second channel of a second plug, wherein the first plug and the second plug correspond to a first select line;
precharging a third channel of a third plug and a fourth channel of a fourth plug, wherein the third channel and the fourth channel correspond to a second select line;
applying one of a program-enable voltage and a program-inhibit voltage to each of the first channel, the second channel, the third channel, and the fourth channel; and
programming memory cells selected from among memory cells included in the first plug, the second plug, the third plug, and the fourth plug.

13. The method according to claim 12, wherein precharging the first channel, the second channel, the third channel, and the fourth channel comprises:
applying a precharge voltage to a first bit line coupled to the first plug;
applying the precharge voltage to a second bit line coupled to the second plug;
applying the precharge voltage to a third bit line coupled to the third plug;
applying the precharge voltage to a fourth bit line coupled to the fourth plug;
applying a pass voltage to word lines coupled in common to the first plug, the second plug, the third plug, and the fourth plug;
simultaneously turning on a first select transistor between the first channel and the first bit line and a second select transistor between the second channel and the second bit line; and
simultaneously turning on a third select transistor between the third channel and the third bit line and a fourth select transistor between the fourth channel and the fourth bit line.

14. The method according to claim 13, wherein:
simultaneously turning on the first select transistor and the second select transistor comprises applying a turn-on voltage to the first select line coupled in common to gates of the first select transistor and the second select transistor, and
simultaneously turning on the third select transistor and the fourth select transistor comprises applying the turn-on voltage to the second select line coupled in common to gates of the third select transistor and the fourth select transistor.

15. The method according to claim 12, wherein applying one of the program-enable voltage and the program-inhibit voltage to each of the first channel, the second channel, the third channel, and the fourth channel comprises:
inputting data to each of a first page buffer, a second page buffer, a third page buffer, and a fourth page buffer coupled to the first plug, the second plug, the third plug, and the fourth plug through a first bit line, a second bit line, a third bit line, and a fourth bit line, respectively; and
outputting, by the first page buffer, the second page buffer, the third page buffer, and the fourth page buffer, one of the program-enable voltage and the program-inhibit voltage to the first bit line, the second bit line, the third bit line, and the fourth bit line, respectively, depending on the data.

16. The method according to claim 12, where programming the selected memory cells comprises:
applying a pass voltage to unselected word lines among word lines coupled in common to the first plug, the second plug, the third plug, and the fourth plug; and
applying a program voltage to a selected word line among the word lines.

17. The method according to claim 12, further comprising when the selected memory cells are included in the first plug, the second plug, the third plug, and the fourth plug, applying the program voltage to the first channel, the second channel, the third channel, and the fourth channel.

18. The method according to claim 12, further comprising:
when the selected memory cells are not included in at least one of the first plug, the second plug, the third plug, and the fourth plug,
applying the program voltage to a channel of a plug in which a selected memory cell is included among the first plug, the second plug, the third plug, and the fourth plug; and
applying the program-inhibit voltage to a channel of a plug in which a selected memory cell is not included among the first plug, the second plug, the third plug, and the fourth plug.

19. The method according to claim 12, further comprising when the selected memory cells are not included in the first plug, the second plug, the third plug, and the fourth plug, applying the program-inhibit voltage to the first channel, the second channel, the third channel, and the fourth channel.

20. A method of operating a memory device, the method comprising:
precharging a first channel of a first plug corresponding to a first select line, a second channel of a second plug corresponding to the first line, a third channel of a third plug corresponding to a second select line, and a fourth channel of a fourth plug corresponding to a second select line;
when the first plug and the third plug are selected plugs, applying a program-enable voltage to the first channel of the first plug and the third channel of the third plug;
when the second plug and the fourth plug are unselected plugs, applying a program-inhibit voltage to the second channel of the second plug and the fourth channel of the fourth plug; and
programming selected memory cells from among memory cells included in the first plug and the third plug of a memory block.
